(19) United States
(12) Patent Application Publication
(10) Pub. No.: US 2024/0126170 A1
(43) Pub. Date: Apr. 18, 2024

(54) METHOD OF MANUFACTURING A SEMICONDUCTOR DEVICE AND PHOTORESIST COMPOSITION

(71) Applicant: Taiwan Semiconductor Manufacturing Company, Ltd., Hsinchu (TW)

(72) Inventors: Chun-Chih HO, Taichung City (TW); Chin-Hsiang Lin, Hsinchu (TW); Ching-Yu Chang, Yuansun Village (TW)

(21) Appl. No.: 18/200,495

(22) Filed: May 22, 2023

Related U.S. Application Data
(60) Provisional application No. 63/410,042, filed on Sep. 26, 2022.

(51) Int. Cl. G03F 7/038; G03F 7/20; H01L 21/027

(52) U.S. Cl. CPC G03F 7/0382; G03F 7/2004; H01L 21/0275

(57) ABSTRACT

A method of manufacturing a semiconductor device includes forming a photoresist layer including a photoresist composition over a substrate. The photoresist layer is selectively exposed to actinic radiation, the selectively exposed photoresist layer is developed to form a pattern in the photoresist layer. The photoresist composition includes a polymer including monomer units with photocleaving promoters, wherein the photocleaving promoters are one or more selected from the group consisting of living free radical polymerization chain transfer agents, electron withdrawing groups, bulky two dimensional (2-D) or three dimensional (3-D) organic groups, N-(acyloxy)phthalimides, and electron stimulated radical generators.

### CROSS-REFERENCE TO RELATED APPLICATION

This application claims priority to U.S. Provisional Patent Application No. 63/410,042, filed Sep. 26, 2022, the entire disclosure of which is incorporated herein by reference.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that were not exposed, can be exploited to remove one region without removing the other, or vice-verse.

However, as the size of individual devices has decreased, process windows for photolithographic processing has become tighter and tighter. As such, advances in the field of photolithographic processing are necessary to maintain the ability to scale down the devices, and further improvements are needed in order to meet the desired design criteria such that the march towards smaller and smaller components may be maintained.

As the semiconductor industry has progressed into nanometer technology process nodes in pursuit of higher device density, higher performance, and lower costs, there have been challenges in reducing semiconductor feature size. Extreme ultraviolet lithography (EUVL) has been developed to form smaller semiconductor device feature size and increase device density on a semiconductor wafer. In extreme ultraviolet (EUV) technology, throughput is one of the key factors in the cost of manufacturing. To further increase the EUV technology fidelity through throughput, the power of the EUV radiation from the EUV exposure tool can be increased or the photoresist (PR) photospeed can be improved. A desired manufacturing goal is >250 wafer/hr throughput.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a process flow of manufacturing a semiconductor device according to embodiments of the disclosure.

FIG. 2 shows a process stage of a sequential operation according to an embodiment of the disclosure.

FIGS. 3A and 3B show process stages of a sequential operation according to an embodiment of the disclosure.

FIG. 4 shows a process stage of a sequential operation according to an embodiment of the disclosure.

FIGS. 5A and 5B show process stages of a sequential operation according to embodiments of the disclosure.

FIGS. 6A and 6B show process stages of sequential operations according to an embodiment of the disclosure.

FIG. 7 shows a process stage of a sequential operation according to an embodiment of the disclosure.

FIGS. 8A and 8B show process stages of a sequential operation according to embodiments of the disclosure.

FIG. 9 shows a process stage of a sequential operation according to an embodiment of the disclosure.

FIGS. 10A and 10B show process stages of a sequential operation according to an embodiment of the disclosure.

FIGS. 11A and 11B show process stages of a sequential operation according to an embodiment of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” The device may be otherwise oriented (rotated 90 degrees or at other orientations) and the spatially relative descriptors used herein may likewise be interpreted accordingly. Further, in the following fabrication processes, there may be one or more additional operations in between the described operations, and the order of operations may be changed. Materials, configurations, dimensions, processes and/or operations as explained with respect to one embodiment may be employed in the other embodiments, and the detailed description thereon may be omitted. Source/drain region(s) may refer to a source or a drain, individually or collectively dependent upon the context.

As semiconductor device pattern features become smaller, photoresist pattern resolution becomes more important. Extreme ultraviolet (EUV) lithography with exposure at 13.5 nm has been used for semiconductor device critical dimensions below 20 nm. In chemically amplified resists (CARs), secondary electrons created by EUV photons activate photoacid generator (PAG) and photo-decomposable quencher (PDQ). However, scum defects may be formed during EUV lithography because of weak absorption of the photoresist by 13.5 nm radiation. Low EUV photon absorption would lead to poor efficiency of PAG/PDQ activation. Undeveloped resist remaining in trenches could lead to bridging lines or footing, resulting in failure of transferring the photoresist pattern to underlying layers. In addition, CARs may suffer from resolution, line-edge-roughness, and sensitivity (RLS) trade-off and insufficient etch resistance resulting in poor line-width-roughness (LWR) and poor local critical dimension uniformity (LCDU). Low dose exposure generally leads to poor line width roughness (LWR) and low critical dimension uniformity (CDU) due to photon shot noise. There are several ways to reduce shot noise, such as, high photoacid generator (PAG) loading and improving acid yield. In addition, it has been found that the photoresist molecular weight (MW) has a positive correlation with line edge roughness (LER) that might alleviate the poor LWR side effect of low dose exposure. Although smaller MW is feasible by synthesis control, too small of a MW may lead to poor spin-on coating. Embodiments of the disclosure address these shortcomings of CARs and provide improved resolution, line-edge-roughness, sensitivity, line-width-roughness, local critical dimension uniformity, and etch resistance. Embodiments of the disclosure are directed to a novel photocleavable photoresist and techniques for manufacturing semiconductor devices.

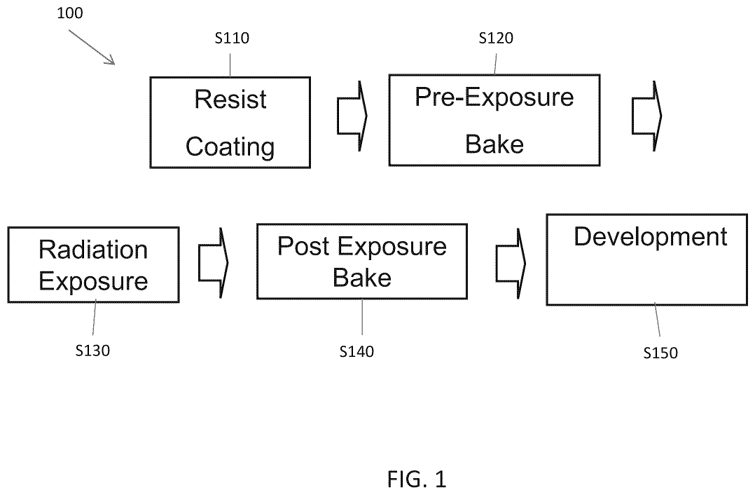

FIG. 1 illustrates a process flow 100 of manufacturing a semiconductor device according to embodiments of the disclosure. In operation S110, a resist composition is prepared. In some embodiments, the resist is a photoresist.

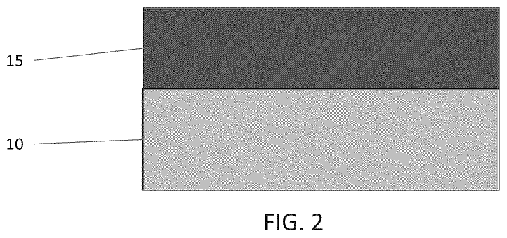

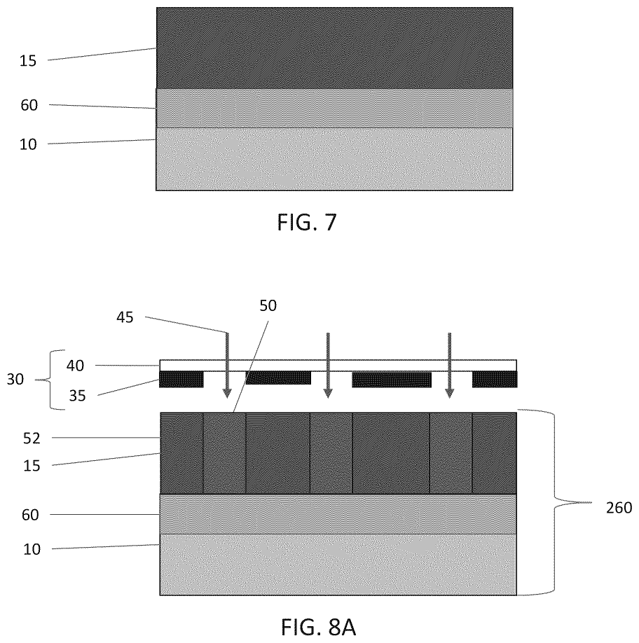

The photoresist composition is coated on a surface of a target layer 60 to be patterned (see FIG. 7) or a substrate 10 in operation S110, in some embodiments, to form a resist layer 15, as shown in FIG. 2. In some embodiments, the resist layer 15 is a photoresist layer. Then, the resist layer 15 undergoes a first baking operation S120 to evaporate solvents in the resist composition in some embodiments. The resist layer 15 is baked at a temperature and time sufficient to cure and dry the resist layer 15 (pre-exposure baking). In some embodiments, the resist layer is heated to a temperature of about 40° C. to 120° C. for about 10 seconds to about 10 minutes.

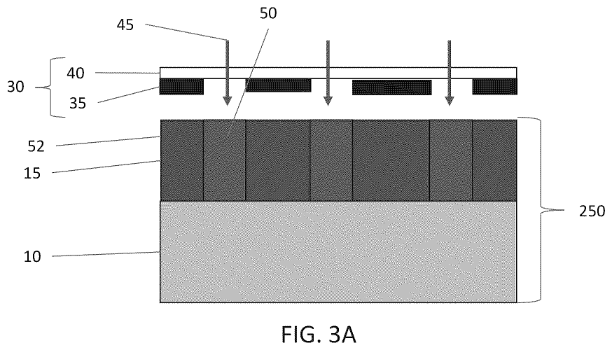

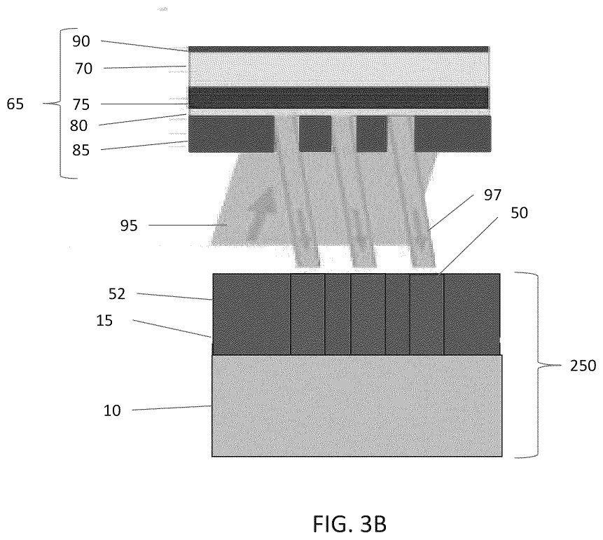

After the first (or pre-exposure) baking operation S120, the photoresist layer 15 is selectively exposed to actinic radiation 45/97 (see FIGS. 3A and 3B) in operation S130. In some embodiments, the photoresist layer 15 is selectively exposed to ultraviolet radiation. In some embodiments, the ultraviolet radiation is deep ultraviolet radiation (DUV). In some embodiments, the ultraviolet radiation is extreme ultraviolet (EUV or XUV) radiation. In some embodiments, the actinic radiation is an electron beam.

As shown in FIG. 3A, the exposure radiation 45 passes through a photomask 30 before irradiating the photoresist layer 15 in some embodiments. In some embodiments, the photomask has a pattern to be replicated in the photoresist layer 15. The pattern is formed by an opaque pattern 35 on the photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz.

In some embodiments, the selective exposure of the photoresist layer 15 to form exposed regions 50 and unexposed regions 52 is performed using extreme ultraviolet lithography. In an extreme ultraviolet lithography operation a reflective photomask 65 is used to form the patterned exposure light in some embodiments, as shown in FIG. 3B. The reflective photomask 65 includes a low thermal expansion glass substrate 70, on which a reflective multilayer 75 of Si and Mo is formed. A capping layer 80 and absorber layer 85 are formed on the reflective multilayer 75. A rear conductive layer 90 is formed on the back side of the low thermal expansion glass substrate 70. In extreme ultraviolet lithography, extreme ultraviolet radiation 95 is directed towards the reflective photomask 65 at an incident angle of about 6°. A portion 97 of the extreme ultraviolet radiation is reflected by the Si/Mo multilayer 75 towards the photoresist coated substrate 10, while the portion of the extreme ultraviolet radiation incident upon the absorber layer 85 is absorbed by the photomask. In some embodiments, additional optics, including mirrors, are between the reflective photomask 65 and the photoresist coated substrate.

The region of the photoresist layer exposed to radiation 50 undergoes a chemical reaction thereby changing its solubility in a subsequently applied developer relative to the region of the photoresist layer not exposed to radiation 52. In some embodiments, the portion of the photoresist layer exposed to radiation 50 undergoes a crosslinking reaction.

Next, the photoresist layer 15 undergoes a second baking operation (or post exposure bake) in operation S140. In some embodiments, the photoresist layer 15 is heated to a temperature of about 70° C. to about 160° C. for about 20 seconds to about 120 seconds. The post-exposure baking may be used in order to assist in the generating, dispersing, and reacting of the acid/base/free radical generated from the impingement of the radiation 45/97 upon the photoresist layer 15 during the exposure. Such assistance helps to create or enhance chemical reactions, which generate chemical differences between the exposed region 50 and the unexposed region 52 within the photoresist layer. These chemical differences also cause differences in the solubility between the exposed region 50 and the unexposed region 52.

In some embodiments during the post exposure baking (heating), the photoresist layer 15 is heated at a temperature in a range of about 40° C. to about 175° C. by controlling the temperature of the heating element 200. In some embodiments, during the post-exposure baking (heating) the photoresist layer 15 is heated at a temperature in a range of about 60° C. to about 160° C. In some embodiments, during the post-exposure baking, the photoresist layer 15 is heated at a temperature in a range of about 100° C. to about 150° C.

In some embodiments, during the post-exposure baking, the photoresist layer 15 is heated for about 45 seconds to about 180 seconds. In some embodiments, the photoresist layer 15 is heated for about 60 seconds to about 120 seconds.

Post-exposure baking at temperatures and for durations of times outside the ranges disclosed herein may result in photoresist patterns having decreased critical dimension uniformity and increased line width roughness.

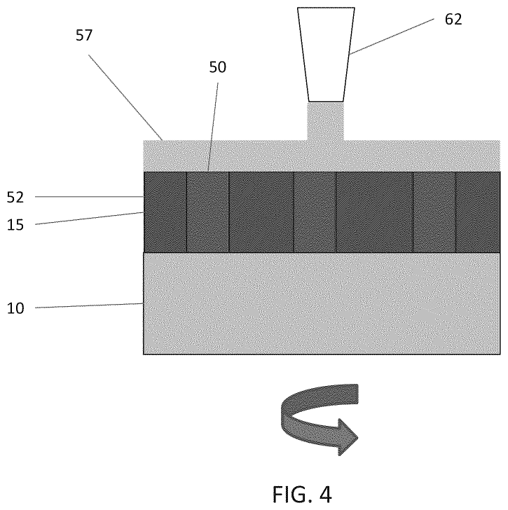

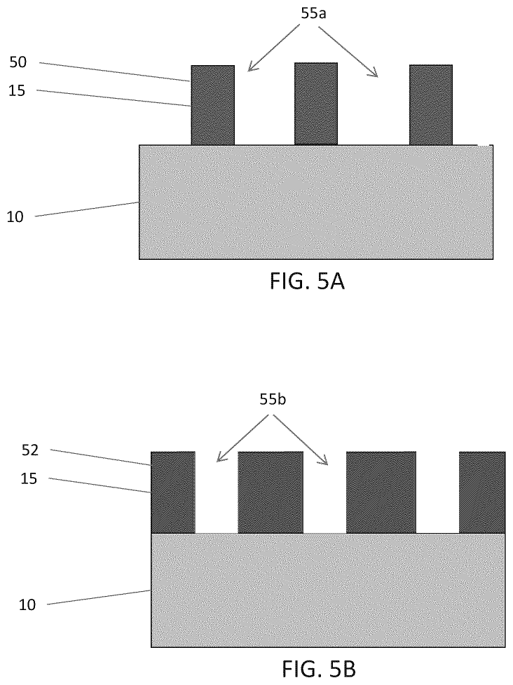

The selectively exposed photoresist layer is subsequently developed by applying a developer to the selectively exposed photoresist layer in operation S150. As shown in FIG. 4, a developer 57 is supplied from a dispenser 62 to the photoresist layer 15. In some embodiments, where the photoresist is a negative-tone resist or a negative-tone developed resist, the unexposed portion of the photoresist layer 52 is removed by the developer 57 forming a pattern of openings 55a in the photoresist layer 15 to expose the substrate 10, as shown in FIG. 5A. In other embodiments, where the photoresist is a positive-tone resist, the exposed portion of the photoresist layer 50 is removed by the developer 57 forming a pattern of openings 55b in the photoresist layer 15 to expose the substrate 10, as shown in FIG. 5B.

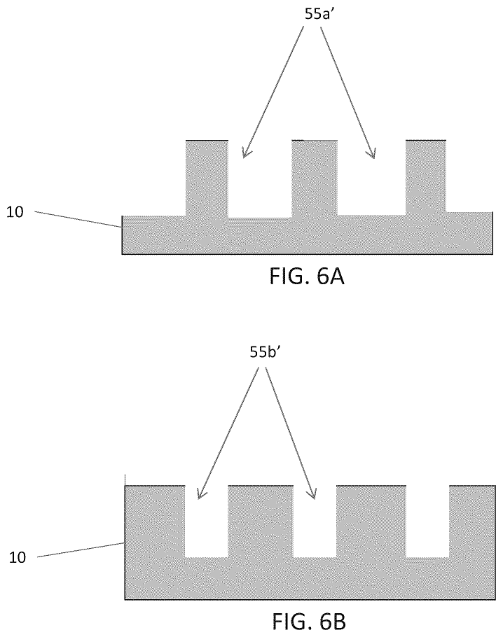

In some embodiments, the pattern of openings 55a, 55b in the photoresist layer 15 are extended into the layer to be patterned or substrate 10 to create a pattern of openings 55a′, 55b′ in the substrate 10, thereby transferring the pattern in the photoresist layer 15 into the substrate 10, as shown in FIGS. 6A and 6B. The pattern is extended into the substrate by etching, using one or more suitable etchants. The portion of the photoresist layer 15 remaining after the development operation is at least partially removed during the etching operation in some embodiments. In other embodiments, the remaining photoresist layer 15 is removed after etching the substrate 10 by using a suitable photoresist stripper solvent or by a photoresist ashing operation.

In some embodiments, the substrate 10 includes a single crystalline semiconductor layer on at least it surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is a silicon layer of an SOI (silicon-on insulator) substrate. In certain embodiments, the substrate 10 is made of crystalline Si.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 10. The germanium concentration of the SiGe buffer layers may increase from 30 atomic % for the bottom-most buffer layer to 70 atomic % for the top-most buffer layer.

In some embodiments, the substrate 10 includes one or more layers of at least one metal, metal alloy, and metal/nitride/sulfide/oxide/silicide having the formula MXₐ, where M is a metal and X is N, S, Se, O, Si, and a is from about 0.4 to about 2.5. In some embodiments, the substrate 10 includes titanium, aluminum, cobalt, ruthenium, titanium nitride, tungsten nitride, tantalum nitride, or combinations thereof.

In some embodiments, the substrate 10 includes a dielectric having at least a silicon or metal oxide or nitride of the formula MX_{b}, where M is a metal or Si, X is N or O, and b ranges from about 0.4 to about 2.5. In some embodiments, the substrate 10 includes silicon dioxide, silicon nitride, aluminum oxide, hafnium oxide, lanthanum oxide, or combinations thereof.

In some embodiments, the substrate 10 refers to any underlying layers over which a resist layer is formed. The substrate 10 is subsequently patterned using photolithographic and etching operations.

The photoresist layer 15 is a photosensitive layer that is patterned by exposure to actinic radiation. Typically, the chemical properties of the photoresist regions struck by incident radiation change in a manner that depends on the type of photoresist used. Photoresist layers 15 may be positive-tone resists or negative tone-resists. A positive-tone resist refers to a photoresist material that when exposed to radiation, such as UV light, becomes soluble in a developer, while the region of the photoresist that is non-exposed (or exposed less) is insoluble in the developer. A negative-tone resist, on the other hand, refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation.

Whether a resist is a positive-tone or negative-tone may depend on the type of developer used to develop the resist. For example, some positive tone photoresists provide a positive pattern, (i.e. —the exposed regions are removed by the developer), when the developer is an aqueous-based developer, such as a tetramethylammonium hydroxide (TMAH) solution. On the other hand, the same photoresist provides a negative pattern (i.e. —the unexposed regions are removed by the developer) when the developer is an organic solvent. Further, in some negative-tone photoresists developed with the TMAH solution, the unexposed regions of the photoresist are removed by the TMAH, and the exposed regions of the photoresist, that undergo cross-linking upon exposure to actinic radiation, remain on the substrate after development. In some embodiments, the resist is a negative-tone developed (NTD) resist. In a NTD resist, instead of the portion of the resist exposed to actinic radiation crosslinking, a developer solvent is selected that preferentially dissolves the unexposed portion of the resist to form the patterned resist.

Some features formed by photolithographic patterning operations may benefit from a positive-tone development, while other features may benefit from a negative-tone development. For example, in an extreme ultraviolet photolithographic patterning operation using an extreme ultraviolet exposure tool having a numerical aperture (NA)=0.33, it is more beneficial in some embodiments to use negative-tone development for forming contact hole patterns having a pitch less than about 30 nm, and use positive-tone development for forming contact hole patterns having a pitch greater than about 30 nm.

Resist compositions according to the present disclosure, such as a photoresist include a polymer or a polymerizable monomer or oligomer along with one or more photoactive compounds (PACs). In some embodiments, the concentration of the polymer, monomer, or oligomer ranges from about 1 wt. % to about 75 wt. % based on the total weight of the resist composition. In other embodiments, the concentration of the polymer, monomer, or oligomer ranges from about 5 wt. % to about 50 wt. %. At concentrations of the polymer, monomer, or oligomer below the disclosed ranges the polymer, monomer, or oligomer has negligible effect on the resist performance. At concentrations above the disclosed range there is no substantial improvement in resist performance or there is degradation in the formation of consistent resist layers.

In some embodiments, the polymerizable monomer or oligomer includes an acrylic acid, an acrylate, a hydroxystyrene, or an alkylene. In some embodiments, the polymer includes a hydrocarbon structure (such as an alicyclic hydrocarbon structure) that contains one or more groups that will decompose (e.g., acid labile groups) or otherwise react when mixed with acids, bases, or free radicals generated by the PACs (as further described below). In some embodiments, the hydrocarbon structure includes a repeating unit that forms a skeletal backbone of the polymer resin. This repeating unit may include acrylic esters, methacrylic esters, crotonic esters, vinyl esters, maleic diesters, fumaric diesters, itaconic diesters, (meth)acrylonitrile, (meth)acrylamides, styrenes, vinyl ethers, lactones, combinations of these, or the like.

Specific structures that are utilized for the repeating unit of the hydrocarbon structure in some embodiments, include one or more of methyl acrylate, ethyl acrylate, n-propyl acrylate, isopropyl acrylate, n-butyl acrylate, isobutyl acrylate, tert-butyl acrylate, n-hexyl acrylate, 2-ethylhexyl acrylate, acetoxyethyl acrylate, phenyl acrylate, 2-hydroxyethyl acrylate, 2-methoxyethyl acrylate, 2-ethoxyethyl acrylate, 2-(2-methoxyethoxy)ethyl acrylate, cyclohexyl acrylate, benzyl acrylate, 2-alkyl-2-adamantyl (meth)acrylate or dialkyl(1-adamantyl)methyl (meth)acrylate, methyl methacrylate, ethyl methacrylate, n-propyl methacrylate, isopropyl methacrylate, n-butyl methacrylate, isobutyl methacrylate, tert-butyl methacrylate, n-hexyl methacrylate, 2-ethylhexyl methacrylate, acetoxyethyl methacrylate, phenyl methacrylate, 2-hydroxyethyl methacrylate, 2-methoxyethyl methacrylate, 2-ethoxyethyl methacrylate, 2-(2-methoxyethoxy)ethyl methacrylate, cyclohexyl methacrylate, benzyl methacrylate, 3-chloro-2-hydroxypropyl methacrylate, 3-acetoxy-2-hydroxypropyl methacrylate, 3-chloroacetoxy-2-hydroxypropyl methacrylate, butyl crotonate, hexyl crotonate, or the like. Examples of the vinyl esters include vinyl acetate, vinyl propionate, vinyl butylate, vinyl methoxyacetate, vinyl benzoate, dimethyl maleate, diethyl maleate, dibutyl maleate, dimethyl fumarate, diethyl fumarate, dibutyl fumarate, dimethyl itaconate, diethyl itaconate, dibutyl itaconate, acrylamide, methyl acrylamide, ethyl acrylamide, propyl acrylamide, n-butyl acrylamide, tert-butyl acrylamide, cyclohexyl acrylamide, 2-methoxyethyl acrylamide, dimethyl acrylamide, diethyl acrylamide, phenyl acrylamide, benzyl acrylamide, methacrylamide, methyl methacrylamide, ethyl methacrylamide, propyl methacrylamide, n-butyl methacrylamide, tert-butyl methacrylamide, cyclohexyl methacrylamide, 2-methoxyethyl methacrylamide, dimethyl methacrylamide, diethyl methacrylamide, phenyl methacrylamide, benzyl methacrylamide, methyl vinyl ether, butyl vinyl ether, hexyl vinyl ether, methoxyethyl vinyl ether, dimethylaminoethyl vinyl ether, or the like. Examples of styrenes include styrene, methyl styrene, dimethyl styrene, trimethyl styrene, ethyl styrene, isopropyl styrene, butyl styrene, methoxy styrene, butoxy styrene, acetoxy styrene, hydroxy styrene, chloro styrene, dichloro styrene, bromo styrene, vinyl methyl benzoate, α-methyl styrene, maleimide, vinylpyridine, vinylpyrrolidone, vinylcarbazole, combinations of these, or the like. Examples of lactones include lactone groups include rings having five to seven members, such as butyrolactone, valerolactone, and caprolactone. In some embodiments, the lactone group is attached to the polymer backbone via an acetyl group, such as an acetylbutyrolactone, acetylvalerolactone, and acetylcaprolactone, although any suitable lactone structure may alternatively be used for the lactone group.

In some embodiments, the polymer includes a polyhydroxystyrene, a polymethyl methacrylate, or a polyhydroxystyrene-t-butyl acrylate, e.g. —

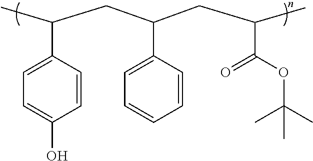

or a polyhydryoxystyrene polymethyl methacrylate, or a polyacetylbutyrolactone, e.g. —

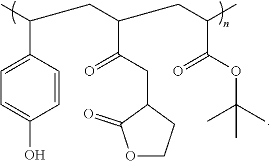

In some embodiments, the repeating unit of the hydrocarbon structure also has either a monocyclic or a polycyclic hydrocarbon structure substituted into it, or the monocyclic or polycyclic hydrocarbon structure is the repeating unit, in order to form an alicyclic hydrocarbon structure. Specific examples of monocyclic structures in some embodiments include bicycloalkane, tricycloalkane, tetracycloalkane, cyclopentane, cyclohexane, or the like. Specific examples of polycyclic structures in some embodiments include adamantane, norbornane, isobornane, tricyclodecane, tetracyclododecane, or the like.

The group which will decompose, otherwise known as a leaving group or, in some embodiments in which the PAC is a photoacid generator, an acid labile group, is attached to the hydrocarbon structure so that, it will react with the acids/bases/free radicals generated by the PACs during exposure. In some embodiments, the group which will decompose is a carboxylic acid group, a fluorinated alcohol group, a phenolic alcohol group, a sulfonic group, a sulfonamide group, a sulfonylimido group, an (alkylsulfonyl) (alkylcarbonyl)methylene group, an (alkylsulfonyl)(alkyl-carbonyl)imido group, a bis(alkylcarbonyl)methylene group, a bis(alkylcarbonyl)imido group, a bis(alkylsylfonyl)methylene group, a bis(alkylsulfonyl)imido group, a tris(alkylcarbonyl) methylene group, a tris(alkylsulfonyl)methylene group, combinations of these, or the like. Specific groups that are used for the fluorinated alcohol group include fluorinated hydroxyalkyl groups, such as a hexafluoroisopropanol group in some embodiments. Specific groups that are used for the carboxylic acid group include acrylic acid groups, methacrylic acid groups, or the like.

In some embodiments, the polymer includes groups that can assist in increasing the adhesiveness of the photoresist layer 15 to underlying structures (e.g., substrate 10). Polar groups may be used to help increase the adhesiveness. Suitable polar groups include hydroxyl groups, cyano groups, or the like, although any suitable polar group may, alternatively, be used.

Optionally, the polymer includes one or more alicyclic hydrocarbon structures that do not also contain a group, which will decompose in some embodiments. In some embodiments, the hydrocarbon structure that does not contain a group which will decompose includes structures such as 1-adamantyl(meth)acrylate, tricyclodecanyl (meth)acrylate, cyclohexyl (meth)acrylate, combinations of these, or the like.

In some embodiments, the resist composition includes a polymer including monomer units with photocleaving promoters. The photocleaving promoters include one or more selected from the group consisting of living free radical polymerization chain transfer agents, electron withdrawing groups, two dimensional (2-D) or three dimensional (3-D) organic groups, N-(acyloxy)phthalimides, and electron stimulated radical generators.

In some embodiments, the resist polymers are synthesized by living free radical polymerization, such as atom transfer radical polymerization (ATRP) or reversible addition-fragmentation chain-transfer (RAFT) polymerization. In some embodiments, the polymer can be reversely unzipped via the polymer terminal units by the use of a chain transfer agent bound to polymer terminal unit. The chain transfer agent assists the polymer chain cleaving during actinic radiation exposure or during the post exposure baking.

In some embodiments, the living free radical polymerization chain transfer agents facilitates a reversible deactivation radical polymerization (RDRP) mechanism. RDRP is a fast and reversible activation/deactivation of propagating chains. Embodiments of the disclosure include three types of RDRP; namely deactivation by catalyzed reversible coupling, deactivation by spontaneous reversible coupling, and deactivation by degenerative transfer (DT). In the RDRP processes, the radicals can propagate with the rate coefficient kₚ by addition of a few monomer units before the deactivation reaction occurs to regenerate the dormant species. Concurrently, two radicals may react with each other to form dead chains with the rate coefficient kₜ. The rates of propagation and termination between two radicals are not influenced by the mechanism of deactivation or the catalyst used in the system. In addition, other chain breaking reactions such as irreversible chain transfer/termination reactions of the propagating radicals with solvent, monomer, polymer, catalyst, additives, etc. introduces additional loss of chain end functionality (CEF). The overall rate coefficient of chain breaking reactions besides the direct termination between two radicals is represented as kₜₓ.

In some embodiments, the living free radical polymerization chain transfer agent is selected from the group consisting of F, Cl, Br, I, a —ON(C(CH₃)₃)₂ group, a (2,2,6,6-tetramethylpiperidin-1-yl)oxyl group, a —SC(═S)Z, and a —SC(═S)SZ group, where Z is a C1-C20 alkyl group, a C6-C20 aryl group, or a C7-C20 aralkyl group, as a polymer backbone terminal unit of the polymer.

Examples of three types of RDRP within the scope of this disclosure include:
1) Deactivation by catalyzed reversible coupling (e.g. ATRP), as shown in Mechanism (I)

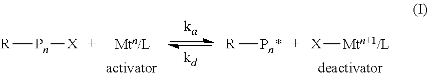

where X is a halogen, including F, Cl, Br, and I.
2) Deactivation by spontaneous reversible coupling (e.g. nitroxide-mediated polymerization (NMP), organometallic mediated radical polymerization (OMRP)), as shown in Mechanism II

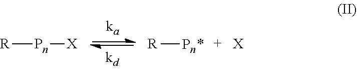

where X is a a —ON(C(CH₃)₃)₂ group or a (2,2,6,6-tetramethylpiperidin-1-yl)oxyl group.
3) Deactivation by degenerative transfer (e.g. RAFT, unsaturated polymethacrylates, I, Te, Ge, Sn, Sb, B, etc. mediated radical polymerization), as shown in Mechanism III

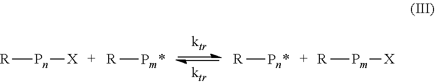

where X is a —SC(═S)Z group or a —SC(═S)SZ group, where Z may be a C1-C20 alkyl group, a C6-C20 aryl group, or a C7-C20 aralkyl group. In some embodiments, Z includes amino groups or cyano groups. P is the polymer chain, R is a polymer chain end group, n and m represent the number of monomer units in the polymer chain, Mtⁿ/L is a transition metal core/ligand complex, kₐ is the activator reaction reate constant, and k_{d} is the deactivator reaction rate constant. In some embodiments R is the same as the repeating groups of polymer P, or is the same as Z. In some embodiments, the RAFT polymerization proceeds using a RAFT agent containing the —SC(═S)Z or —SC(═S)SZ group selected from the group consisting of pentaerythritol tetrakis[2-(dodecylthiocarbonothioylthio)-2-methylpropionate], 3-butenyl 2-(dodecylthiocarbonothioylthio)-2-methylpropionate, 2-(dodecylthiocarbonothioylthio)-2-methylpropionic acid, 4-cyano-4-(phenylcarbonothioylthio)pentanoic acid, 4-cyano-4[(dodecylsulfanylthiocarbonyl)sulfanyl]pentanoic acid, 2-nitro-5-(2-propynyloxy)benzyl 4-cyano-4-(phenylcarbonothioylthio)pentanoate, 1,1,1-tris[(dodecylthiocarbonothioylthio)-2-methylpropionate]ethane, benzyl benzodithioate, 4-cyano-4(pehnylcarbonothioythio)pentanoic acid N-succinimidyl ester, 2-(dodecylthiocarbonothioylthio)-2-methylpropionic acid, 4-((((2-carboxyethyl)thio)carbonothioyl)thio)-4-cyanopentanoic acid, 2-cyanobutan-2-yl 4-chloro-3,5-dimethyl-1H-pyrazole-1-carbodithioate, 2-[[(2-carboxyethyl)sulfanythiocarbonyl]-sulfanyl]propanoic acid, ethyl 2-methyl-2-(phenylthiocarbonylthio)propionate, ethyl 2-(phenylcarbonylthioylthio)propionate, DDMAT terminated and azide terminated poly(tert-butyl acrylate), cyanomethyl diphenylcarbamodithioate, benzyl 1H-pyrrole-1-carbothioate, 2-(dodecylthiocarbonothioylthio)-2-methylpropionic acid 3-axido-1-propanol ester, 2-(dodecylthiocarbonothioylthio)propionic acid, ethyl 2-(phenylcarbonothioylthio)-2-phenylacetate, 1-(methoxycarbonyl)ethyl benzodithioate, 4-cyano-4-[(dodecylsulfanylthiocarbonyl)sulfanyl]pentanol, methyl 2-(dodecylthiocarbonothioylthio)-2-methylpropionate, 2-(dodecylthiocarbonothioylthio)-2-methylpropionic acid N-hydroxysuccinimide ester, 2-(dodecylthiocarbonothioylthio)-2-methylpropionic acid pentafluorophenyl ester, 3,5-bis(2-dodecylthiocarbonothioylthio-1-oxopropoxy)benzoic acid, phthalimidomethyl butyl trithiocarbonate, S,S-dibenzyl trithiocarbonate, 2-cyanobutanyl-2-yl 3,5-dimethyl-1H-pyrazole-1-carbodithioate, cyanomethyl (3,5-dimethyl-1H-pyrazole)-carbodithioate, 2-(4-methoxyphenylcarbonothioylthio)ethanoic acid, poly(ethylene glycol) methyl ether (2-methyl-2-propionic acid dodecyl trithiocarbonate), poly(ethylene glycol) methyl ether 2-(dodecylthiocarbonothioylthio)-2-methylpropionate, poly(ethylene glycol) methyl ether (4-cyano-4-pentanoate dodecyl trithiocarbonate), poly(ethylene glycol) methyl ether 4-cyano-4-[(dodecylsulfanylthiocarbonyl)sulfanyl]pentanoate, cyanomethyl dodecyl trithiocarbonate, 2-phenyl-2-propyl benzodithioate, N,N′-dimethyl N,N′-di(pyridinyl)thiuram disulfide, 4-cyano-4-(phenylcarbonothioylthio)pentanoic acid, 4-cyano-4-[(dodecylsulfanylthiocarbonyl)sulfanyl]pentanoic acid, 2-cyano-2-propyl dodecyl trithiocarbonate, 2-cyano-2-propyl 4-cyanobenzodithioate, 2-cyanopropan-2-yl N-methyl-N-(pryidin-4-yl)carbamodithioate, cyanomethyl methyl(4-pyridyl)carbamodithioate, methyl 2-[methyl(4-pryidinyl)carbamothioylthio]propionate, bis-MPA-RAFT dendrimer trimethylol propane, poly(L-lactide) 4-cyano-4-[(dodecylsulfanylthiocarbonyl)sulfanyl]pentanoate, bis(thiobenzoyl) disulfide, bis(dodecylsulfanylthiocarbamoyl) disulfide, poly(ethylene glycol) 4-cyano-4-(phenylcarbonothioylthio)pentanoate, DDMAT terminated polystyrene, poly(D,L-lactide) 4-cyano-4-[(dodecylsulfanylthiocarbonyl)sulfanyl]pentonate terminated, DDMAT terminated poly(hydroxyethyl methacrylate), 2-cyano-2-propyl benzodithioate, DDMAT terminated poly(acrylic acid), cyanomethyl methyl(phenyl)carbamodithioate, poly(ethylene glycol) bis[2-(dodeclthiocarbonothioylthio)-2-methylpropionate], and DDMAT terminated poly (N,N-dimethylacrylamide).

When the RAFT agent is symmetric, such as pentaerythritol tetrakis[2-(dodecylthiocarbonothioylthio)-2-methylpropionate], 1,1,1-tris[(dodecylthiocarbonothioylthio)-2-methylpropionate]ethane, S,S-dibenzyl trithiocarbonate, bis-MPA-RAFT dendrimer trimethylol propane, bis(thiobenzoyl) disulfide, bis(dodecylsulfanylthiocarbamoyl) disulfide, or 3,5-bis(2-dodecylthiocarbonothioylthio-1-oxopropoxy)benzoic acid, the polymerization proceeds along each of the symmetric directions.

In some embodiments, the electron withdrawing groups are one or more of a halogen (e.g. —F, Cl, Br, I), —C(═O), —C(═O)R, —C(═O)OR, —C(═O)OH, —C(═O)Cl, —CF₃, —CN, —SO₃H, —(NH₃)⁺, —(NR₃)⁺, —N⁺(═O)O, where R is a C1-C40 alkyl group, a C1-C40 alkoxy group, a C1-C40 alkyl ester group, a C1-C40 hydroxyalkyl group, a C1-C40 alkyl amine group, a C1-C40 alkyl group substituted with an acid labile group (ALG) at a —C(═O)— or —C(═O)O— site pendant to the alkyl group, a C1-C40 alkene group, a C6-C40 aryl group, a C1-C40 alkyl amide group, and a C7-C40 aralkyl group.

In some embodiments, the 2-D or 3-D organic groups include a 2-D or 3-D organic group selected from the group consisting of a C4-C16 tert-alkyl group, a C6-C12 cycloalkyl group, a phenyl group, a napthalenyl group, a phenanthrenyl group, an anthracenyl group, a triphenyl methyl group, a norbornyl group, a cubanyl group, an adamantyl group, a basketanyl group, and combinations thereof. In an embodiment, the 2-D or 3-D group is substituted with one or more of a halogen, an —OH, a C1-C40 alkyl group, a C2-C40 alkyl ether group, a C2-C40 alkyl ester group, a C1-C40 hydroxyalkyl group, a C1-C40 alkyl amine group, a C2-C40 alkene group, a phenyl group, an anthracenyl group, a C1-C40 alkyl carboxylic acid group, and a C1-C40 alkyl amide group. In some embodiments, the 2-D or 3-D organic group is a bulky group. Bulky groups introduce steric hindrance effects to the polymer, which affect the photocleaving kinetics. In some embodiments, the bulky groups include a tert-butyl group, a cyclohexane group, a phenyl, an adamantyl group, or a triphenyl methyl group.

In some embodiments, the N-(acyloxy)phthalimides include a N-(acyloxy)phthalimide group

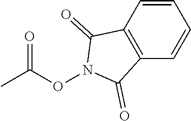

or a substituted N-(acyloxy)phthalimide group

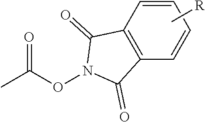

where R is a C1-C40 alkyl group, a C1-C40 alkoxide group, a C1-C40 alkyl ester group, a C1-C40 hydroxyalkyl group, a C1-C40 alkyl amine group, a C1-C40 alkyl substituted with an acid labile group via a —C(═O)— or a —C(═O)O— linkage, a C2-C40 alkene group, a C6-C40 aryl group, a C7-C40 aralkyl group, a phenyl group, a naphthalenyl group, an anthracenyl group, a phenanthrenyl group, a C1-C40 alkyl carboxylic acid group, or a C1-C40 alkyl amide group.

In some embodiments, the electron stimulated radical generator is a 1,4-benzoquinone group or a or a substituted 1,4-benzoquinone, as shown below:

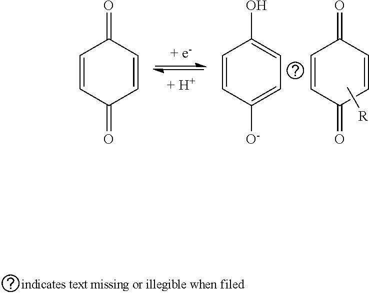

where R is a C1-C40 alkyl group, a C1-C40 alkoxide group, a C1-C40 alkyl ester group, a C1-C40 hydroxyalkyl group, a C1-C40 alkyl amine group, a C1-C40 alkyl substituted with an acid labile group via a —CO— or a —COO— linkage, a C2-C40 alkene group, a C6-C40 aryl group, a C7-C40 aralkyl group, a phenyl group, a naphthalenyl group, an anthracenyl group, a phenanthrenyl group, a C1-C40 alkyl carboxylic acid group, or a C1-C40 alkyl amide group. In some embodiments, the resist composition an electron stimulated radical generator as an additive in addition to the polymer and other resist composition components. In an embodiment, the electron stimulated radical generator additive is 1,4-benzoquinone or a benzoquinone substituted with a a C1-C40 alkyl group, a C1-C40 alkoxide group, a C1-C40 alkyl ester group, a C1-C40 hydroxyalkyl group, a C1-C40 alkyl amine group, a C1-C40 alkyl substituted with an acid labile group via a —CO— or a —COO— linkage, a C2-C40 alkene group, a C6-C40 aryl group, a C7-C40 aralkyl group, a phenyl group, a naphthalenyl group, an anthracenyl group, a phenanthrenyl group, an C1-C40 alkyl carboxylic acid group, or a C1-C40 alkyl amide group.

In some embodiments, the electron stimulated radical generator includes phosphines, boranes, or alumanes. The electron simulated radical generator may include a combination of a phosphine and a borane or alumane, a combination of a phosphine and a triphenyl (CPh₃⁺) cation or silylium (SiR₃⁺) cation, or a combination of a borane and a triarylamine. In some embodiments, the borane is B(C₆F₅)₃. In some embodiments, the phosphine includes trimesityl phosphine (Mes₃P), 2, 4, 6-triisopropylphenyl phosphine (PTipp), P(C₆F₅)₃, P(C₆(CH₃))₃, P(C(C₄H₉)₃)₃. In some embodiments, the alumane is Al(C₆F₅)₃. In some embodiments, the silylium cation is Si((CH₃)₂CHOH)₃⁺, Si(C(C₄H₉)₃)₃⁺, Si(C₆(CH₃))₃⁺, or Si(C₂H₅)₃⁺. In some embodiments, the triarylamine is a triphenylamine. In some embodiments, the triarylamine is a cyclic triarylamine, including a methylene-bridged triphenylamine.

In some embodiments, a concentration of the electron stimulated radical generator (ESRG) additive in the resist composition ranges from about 1 wt. % to about 60 wt. % based on the total weight of the ESRG additive, the polymer, photoactive compound, and quencher.

In some embodiments, the polymer including monomer units with photocleaving promoters is made of monomer units u, v, x, y, and z represented by a structure (IV):

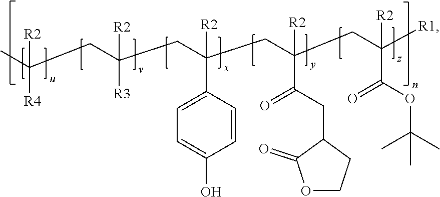

where: R1 is selected from the group consisting of F, Cl, Br, I, a —ON(C(CH₃)₃)₂ group, a (2,2,6,6-tetramethylpiperidin-1-yl)oxyl group, a —SC(═S)Z group, and a —SC(═S)SZ group where Z may be a C1-C20 alkyl group, a C6-C20 aryl group, or a C7-C20 aralkyl group, where any of the groups may include amino groups or cyano groups; R2 is selected from the group consisting of H, a halogen (e.g. —F, Cl, Br, I), —C(═O), —C(═O)R, —C(═O)OR, —C(═O)OH, —C(═O)Cl, —CF₃, —CN, —SO₃H, —(NH₃)⁺, —(NR₃)⁺, —N⁺(═O)O, where R is a C1-C40 alkyl group, a C1-C40 alkoxy group, a C1-C40 alkyl ester group, a C1-C40 hydroxyalkyl group, a C1-C40 alkyl amine group, a C1-C40 alkyl group substituted with an acid labile group (ALG) at a —C(═O)— or —C(═O)O— site pendant to the alkyl group, a C1-C40 alkene group, a C6-C40 aryl group, a C1-C40 alkyl amide group, a C7-C40 aralkyl group, a C4-C16 tert-alkyl group, a C6-C12 cycloalkyl group, a phenyl group, a napthalenyl group, a phenanthrenyl group, an anthracenyl group, a triphenyl methyl group, a norbornyl group, a cubanyl group, an adamantyl group, a basketanyl group, and combinations thereof; R3 is a substituted or unsubstituted N-(acyloxy)phthalimide; and R4 is an electron stimulated radical generator. In some embodiments n ranges from about 10 to about 1,000, and in other embodiments, n ranges from about 20 to about 500.

A molar concentration of each monomer unit u, v, x, y, and z ranges from 0% to 100%, wherein at least one of the monomer units u, v, x, y, and z is included in the polymer. In some embodiments, the polymer is made of 1% to 100% of monomer units u or v. Thus, the polymer structure (IV) may be comprised of only one of the monomer units u, v, x, y, or z; all the monomer units u, v, x, y, and z; or any combination thereof. R2 is optional on each monomer unit, u, v, x, y, or z. Thus, the polymer structure (IV) may include only hydrogen as the R2 groups, or each of the monomer units may contain an R2 group other than hydrogen, or any combination of the monomer units u, v, x, y, and z may contain an R2 group other than hydrogen. For example, about 10% to about 60% of the monomer units contain an R2 group other than hydrogen in some embodiments.

In some embodiments, the substituent R1 is a living free radical polymerization chain transfer agent and the substituent R2 is an electron withdrawing group or a 2-D or 3-D organic group. R1 helps polymer cleavage via an unzipping pathway. Including an R2 group other than hydrogen makes it easier to cleave the polymer than without an R2 group other than hydrogen. The location of the R2 substituent is not limited to monomer units with the R3 substituent, the R4 substituent, the phenol group, the lactone group, or the acrylate group. The R3 substituent causes the polymer to be cleaved through pi-scission cleavage from its reactive site. The R4 substituent can be attached to the polymer or may be a photoresist composition additive to promote radical generation after exposure thereby promoting polymer cleavage.

In some embodiments, the resist compositions include a metal to improve EUV radiation absorption. The metal-containing resists of the present disclosure may include metallic cores complexed with one or more ligands in a solvent. In some embodiments, the resist includes metal particles. In some embodiments, the metal particles are nanoparticles. As used herein, nanoparticles are particles having an average particle size between about 1 nm and about 20 nm. In some embodiments, the metallic cores, including from 1 to about 18 metal particles, are complexed with one or more organic ligands in a solvent. In some embodiments, the metallic cores include 3, 6, 9, or more metal nanoparticles complexed with one or more organic ligands in a solvent.

In some embodiments, the metal particle is one or more of titanium (Ti), zinc (Zn), zirconium (Zr), nickel (Ni), cobalt (Co), manganese (Mn), copper (Cu), iron (Fe), strontium (Sr), tungsten (W), vanadium (V), chromium (Cr), tin (Sn), hafnium (Hf), indium (In), cadmium (Cd), molybdenum (Mo), tantalum (Ta), niobium (Nb), aluminum (Al), cesium (Cs), barium (Ba), lanthanum (La), cerium (Ce), silver (Ag), antimony (Sb), combinations thereof, or oxides thereof.

In some embodiments, the metal nanoparticles have an average particle size between about 2 nm and about 5 nm. In some embodiments, the amount of metal nanoparticles in the resist composition ranges from about 0.5 wt. % to about 15 wt. % based on the weight of the nanoparticles and the solvent. In some embodiments, the amount of nanoparticles in the resist composition ranges from about 5 wt. % to about 10 wt. % based on the weight of the nanoparticles and the solvent. In some embodiments, the concentration of the metal particles ranges from 1 wt. % to 7 wt. % based on the weight of the solvent and the metal particles. Below about 0.5 wt. % metal nanoparticles, the resist coating may be too thin. Above about 15 wt. % metal nanoparticles, the resist coating may be too thick and viscous.

In some embodiments, the metallic core is complexed by a ligand, wherein the ligand includes branched or unbranched, cyclic or non-cyclic, saturated organic groups, including C1-C7 alkyl groups or C1-C7 fluoroalkyl groups. The C1-C7 alkyl groups or C1-C7 fluoroalkyl groups include one or more substituents selected from the group consisting of —CF₃, —SH, —OH, ═O, —S—, —P—, —PO₂, —C(═O)SH, —C(═O)OH, —C(═O)O—, —O—, —N—, —C(═O)NH, —SO₂OH, —SO₂SH, —SOH, and —SO₂—. In some embodiments, the ligand includes one or more substituents selected from the group consisting of —CF₃, —OH, —SH, and —C(═O)OH substituents.

In some embodiments, the ligand is a carboxylic acid or sulfonic acid ligand. For example, in some embodiments, the ligand is a methacrylic acid. In some embodiments, the metal particles are nanoparticles, and the metal nanoparticles are complexed with ligands including aliphatic or aromatic groups. The aliphatic or aromatic groups may be unbranched or branched with cyclic or noncyclic saturated pendant groups containing 1-9 carbons, including alkyl groups, alkenyl groups, and phenyl groups. The branched groups may be further substituted with oxygen or halogen. In some embodiments, the second ligand is a branched or unbranched, aliphatic or aromatic, substituted or unsubstituted carboxylic acid or sulfonic acid ligand, wherein when the second ligand is substituted, the substituent selected from one or more of a C1-C9 alkyl group, a C2-C9 alkenyl group, or a C6-C9 phenyl group.

In some embodiments, each metal particle is complexed by 1 to 25 ligand units. In some embodiments, each metal particle is complexed by 3 to 18 ligand units.

In some embodiments, the resist composition includes about 0.1 wt. % to about 20 wt. % of the ligands based on the total weight of the resist composition. In some embodiments, the resist includes about 1 wt. % to about 10 wt. % of the ligands. In some embodiments, the ligand concentration is about 10 wt. % to about 40 wt. % based on the weight of the metal particles and the weight of the ligands. Below about 10 wt. %, ligand, the organometallic photoresist does not function well. Above about 40 wt. %, ligand, it is difficult to form a consistent photoresist layer. In some embodiments, the ligand(s) is dissolved at about a 5 wt. % to about 10 wt. % weight range in a coating solvent, such as propylene glycol methyl ether acetate (PGMEA) based on the weight of the ligand(s) and the solvent.

The resist composition solvent can be any suitable solvent. In some embodiments, the solvent is one or more of propylene glycol methyl ether acetate (PGMEA), propylene glycol monomethyl ether (PGME), 1-ethoxy-2-propanol (PGEE), 7-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), or 2-heptanone (MAK).

In some embodiments, the metallic core/ligand complexes are formed by mixing the metallic particles with the ligands. In some embodiments, the metallic core/ligand complexes are formed spontaneously upon mixing the metallic particles with the ligands. In other embodiments, the mixture of metallic particles and ligands are heated to a temperature of about 80° C. to about 150° C. for about 30 seconds to about 240 seconds to form the metallic core/ligand complexes.

Some embodiments of the photoresist include one or more photoactive compounds (PACs). The PACs are photoactive components, such as photoacid generators (PAG), photobase (PBG) generators, photo decomposable bases (PDB), free-radical generators, or the like. The PACs may be positive-acting or negative-acting. In some embodiments in which the PACs are a photoacid generator, the PACs include halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, combinations of these, or the like.

Specific examples of photoacid generators include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy)-acetate and t-butyl-α-(p-toluenesulfonyloxy)-acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl)sulfonate and bis-(di-t-butylphenyl)iodonium camphanylsulfonate, perfluoroalkanesulfonates such as perfluoropentanesulfonate, perfluorooctanesulfonate, perfluoromethanesulfonate, aryl (e.g., phenyl or benzyl)triflates such as triphenylsulfonium triflate or bis-(t-butylphenyl)iodonium triflate; pyrogallol derivatives (e.g., trimesylate of pyrogallol), trifluoromethanesulfonate esters of hydroxyimides, α,α′-bis-sulfonyl-diazomethanes, sulfonate esters of nitro-substituted benzyl alcohols, naphthoquinone-4-diazides, alkyl disulfones, or the like.

In some embodiments in which the PACs are free-radical generators, the PACs include n-phenylglycine; aromatic ketones, including benzophenone, N,N′-tetramethyl-4,4′-diaminobenzophenone, N,N′-tetraethyl-4,4′-diaminobenzophenone, 4-methoxy-4′-dimethylaminobenzo-phenone, 3,3′-dimethyl-4-methoxybenzophenone, p,p′-bis(dimethylamino)benzo-phenone, p,p′-bis(diethylamino)-benzophenone; anthraquinone, 2-ethylanthraquinone; naphthaquinone; and phenanthraquinone; benzoins including benzoin, benzoinmethylether, benzoinisopropylether, benzoin-n-butylether, benzoin-phenylether, methylbenzoin and ethylbenzoin; benzyl derivatives, including dibenzyl, benzyldiphenyldisulfide, and benzyldimethylketal; acridine derivatives, including 9-phenylacridine, and 1,7-bis(9-acridinyl)heptane; thioxanthones, including 2-chlorothioxanthone, 2-methylthioxanthone, 2,4-diethylthioxanthone, 2,4-dimethylthioxanthone, and 2-isopropylthioxanthone; acetophenones, including 1,1-dichloroacetophenone, p-t-butyldichloro-acetophenone, 2,2-diethoxyacetophenone, 2,2-dimethoxy-2-phenylacetophenone, and 2,2-dichloro-4-phenoxyacetophenone; 2,4,5-triarylimidazole dimers, including 2-(o-chlorophenyl)-4,5-diphenylimidazole dimer, 2-(o-chlorophenyl)-4,5-di-(m-methoxyphenyl imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, 2-(2,4-dimethoxyphenyl)-4,5-diphenylimidazole dimer and 2-(p-methylmercaptophenyl)-4,5-diphenylimidazole dimmer; combinations of these, or the like.

In some embodiments, the PAC includes a quencher. In some embodiments, the quenchers include photobase generators and photo decomposable bases. In some embodiments, the quencher includes primary, secondary, and tertiary amines. In embodiments in which the PACs are photobase generators (PBG), the PBGs include quaternary ammonium dithiocarbamates, a aminoketones, oxime-urethane containing molecules such as dibenzophenoneoxime hexamethylene diurethan, ammonium tetraorganylborate salts, and N-(2-nitrobenzyloxycarbonyl)cyclic amines, combinations of these, or the like.

In some embodiments in which the PACs are photo decomposable bases (PBD), the PBDs include triphenylsulfonium hydroxide, triphenylsulfonium antimony hexafluoride, or triphenylsulfonium triflate.

In some embodiments, the concentration of the photoactive compound ranges from about 0.1 wt. % to about 20 wt. % based on the total weight of the resist composition. In other embodiments, the concentration of the photoactive compound ranges from about 1 wt. % to about 15 wt. %. At concentrations of the photoactive compound below the disclosed ranges, the photoactive compound may have negligible effect on the resist performance. At concentrations above the disclosed range, there may be no substantial improvement in resist performance.

As one of ordinary skill in the art will recognize, the chemical compounds listed herein are merely intended as illustrated examples of the PACs and are not intended to limit the embodiments to only those PACs specifically described. Rather, any suitable PAC may be used, and all such PACs are fully intended to be included within the scope of the present embodiments.

In some embodiments, a cross-linking agent is added to the photoresist. The cross-linking agent reacts with one group from one of the hydrocarbon structures in the polymer and also reacts with a second group from a separate one of the hydrocarbon structures in order to cross-link and bond the two hydrocarbon structures together. This bonding and cross-linking increases the molecular weight of the polymer products of the cross-linking reaction and increases the overall linking density of the photoresist. Such an increase in density and linking density helps to improve the resist pattern.

In some embodiments the cross-linking agent has the following structure:

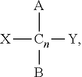

wherein C is carbon, n ranges from 1 to 15; A and B independently include a hydrogen atom, a hydroxyl group, a halide, an aromatic carbon ring, or a straight or cyclic alkyl, alkoxyl/fluoro, alkyl/fluoroalkoxyl chain having a carbon number of between 1 and 12, and each carbon C contains A and B; a first terminal carbon C at a first end of a carbon C chain includes X and a second terminal carbon C at a second end of the carbon chain includes Y, wherein X and Y independently include an amine group, a thiol group, a hydroxyl group, an isopropyl alcohol group, or an isopropyl amine group, except when n=1 then X and Y are bonded to the same carbon C. Specific examples of materials that may be used as the cross-linking agent include the following:

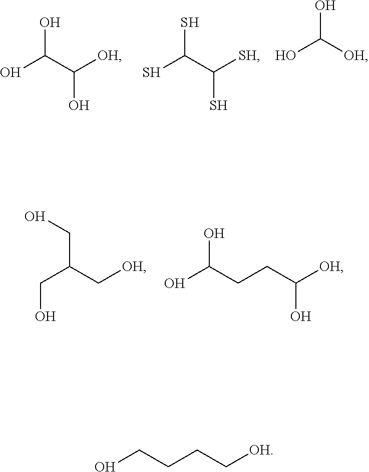

Alternatively, instead of or in addition to the cross-linking agent being added to the photoresist composition, a coupling reagent is added in some embodiments, in which the coupling reagent is added in addition to the cross-linking agent. The coupling reagent assists the cross-linking reaction by reacting with the groups on the hydrocarbon structure in the polymer resin before the cross-linking reagent, allowing for a reduction in the reaction energy of the cross-linking reaction and an increase in the rate of reaction. The bonded coupling reagent then reacts with the cross-linking agent, thereby coupling the cross-linking agent to the polymer resin.

Alternatively, in some embodiments in which the coupling reagent is added to the photoresist without the cross-linking agent, the coupling reagent is used to couple one group from one of the hydrocarbon structures in the polymer resin to a second group from a separate one of the hydrocarbon structures in order to cross-link and bond the two polymers together. However, in such an embodiment the coupling reagent, unlike the cross-linking agent, does not remain as part of the polymer, and only assists in bonding one hydrocarbon structure directly to another hydrocarbon structure.

In some embodiments, the coupling reagent has the following structure:

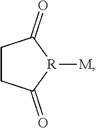

where R is a carbon atom, a nitrogen atom, a sulfur atom, or an oxygen atom; M includes a chlorine atom, a bromine atom, an iodine atom, —NO₂; —SO₃—; —H—; —CN; —NCO, —OCN; —CO₂—; —OH; —OR*, —OC(O)CR*; —SR, —SO₂N(R*)₂; —SO₂R*; SOR; —OC(O)R*; —C(O)OR*; —C(O)R*; —Si(OR*)₃; —Si(R*)₃; epoxy groups, or the like; and R* is a substituted or unsubstituted C1-C12 alkyl, C1-C12 aryl, C1-C12 aralkyl, or the like. Specific examples of materials used as the coupling reagent in some embodiments include the following:

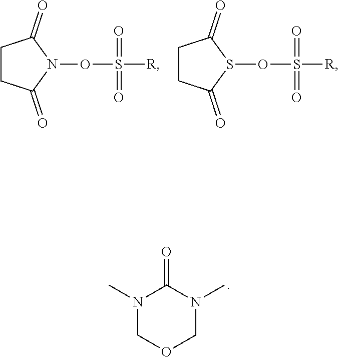

Other additives to the resist composition, in some embodiments, is a stabilizer, which assists in preventing undesired diffusion of the acids generated during exposure of the photoresist. In some embodiments, the stabilizer includes nitrogenous compounds, including aliphatic primary, secondary, and tertiary amines; cyclic amines, including piperidines, pyrrolidines, morpholines; aromatic heterocycles, including pyridines, pyrimidines, purines; imines, including diazabicycloundecene, guanidines, imides, amides, or the like. Alternatively, ammonium salts are also be used for the stabilizer in some embodiments, including ammonium, primary, secondary, tertiary, and quaternary alkyl- and aryl-ammonium salts of alkoxides, including hydroxide, phenolates, carboxylates, aryl and alkyl sulfonates, sulfonamides, or the like. Other cationic nitrogenous compounds, including pyridinium salts and salts of other heterocyclic nitrogenous compounds with anions, such as alkoxides, including hydroxide, phenolates, carboxylates, aryl and alkyl sulfonates, sulfonamides, or the like, are used in some embodiments.

Another additive in some embodiments of the resist is a dissolution inhibitor to help control dissolution of the resist during development. In an embodiment bile-salt esters may be utilized as the dissolution inhibitor. Specific examples of dissolution inhibitors in some embodiments include cholic acid, deoxycholic acid, lithocholic acid, t-butyl deoxycholate, t-butyl lithocholate, and t-butyl-3-acetyl lithocholate.

Another additive in some embodiments of the resist is a plasticizer. Plasticizers may be used to reduce delamination and cracking between the photoresist and underlying layers (e.g., the layer to be patterned). Plasticizers include monomeric, oligomeric, and polymeric plasticizers, such as oligo- and polyethyleneglycol ethers, cycloaliphatic esters, and non-acid reactive steroidaly-derived materials. Specific examples of materials used for the plasticizer in some embodiments include dioctyl phthalate, didodecyl phthalate, triethylene glycol dicaprylate, dimethyl glycol phthalate, tricresyl phosphate, dioctyl adipate, dibutyl sebacate, triacetyl glycerine, or the like.

A coloring agent is another additive included in some embodiments of the resist. The coloring agent observers examine the photoresist and find any defects that may need to be remedied prior to further processing. In some embodiments, the coloring agent is a triarylmethane dye or a fine particle organic pigment. Specific examples of materials in some embodiments include crystal violet, methyl violet, ethyl violet, oil blue #603, Victoria Pure Blue BOH, malachite green, diamond green, phthalocyanine pigments, azo pigments, carbon black, titanium oxide, brilliant green dye (C. I. 42020), Victoria Pure Blue FGA (Linebrow), Victoria BO (Linebrow) (C. I. 42595), Victoria Blue BO (C. I. 44045), rhodamine 6G (C. I. 45160), benzophenone compounds, such as 2,4-dihydroxybenzophenone and 2,2′,4,4′-tetrahydroxybenzophenone; salicylic acid compounds, such as phenyl salicylate and 4-t-butylphenyl salicylate; phenylacrylate compounds, such as ethyl-2-cyano-3,3-diphenylacrylate, and 2′-ethylhexyl-2-cyano-3,3-diphenylacrylate; benzotriazole compounds, such as 2-(2-hydroxy-5-methylphenyl)-2H-benzotriazole, and 2-(3-t-butyl-2-hydroxy-5-methylphenyl)-5-chloro-2H-benzotriazole; coumarin compounds, such as 4-methyl-7-diethylamino-1-benzopyran-2-one; thioxanthone compounds, such as diethylthioxanthone; stilbene compounds, naphthalic acid compounds, azo dyes, phthalocyanine blue, phthalocyanine green, iodine green, Victoria blue, crystal violet, titanium oxide, naphthalene black, Photopia methyl violet, bromphenol blue and bromcresol green; laser dyes, such as Rhodamine G6, Coumarin 500, DCM (4-(dicyanomethylene)-2-methyl-6-(4-dimethylaminostyryl)-4H pyran)), Kiton Red 620, Pyrromethene 580, or the like. Additionally, one or more coloring agents may be used in combination to provide the desired coloring.

Adhesion additives are added to some embodiments of the resist to promote adhesion between the photoresist and an underlying layer upon which the photoresist has been applied (e.g., the layer to be patterned). In some embodiments, the adhesion additives include a silane compound with at least one reactive substituent such as a carboxyl group, a methacryloyl group, an isocyanate group and/or an epoxy group. Specific examples of the adhesion components include trimethoxysilyl benzoic acid, γ-methacryloxypropyl trimethoxy silane, vinyltriacetoxysilane, vinyltrimethoxysilane, γ-isocyanatepropyl triethoxy silane, γ-glycidoxypropyl trimethoxy silane, β-(3,4-epoxycyclohexyl)ethyl trimethoxy silane, benzimidazoles and polybenzimidazoles, a lower hydroxyalkyl substituted pyridine derivative, a nitrogen heterocyclic compound, urea, thiourea, an organophosphorus compound, 8-oxyquinoline, 4-hydroxypteridine and derivatives, 1,10-phenanthroline and derivatives, 2,2′-bipyridine and derivatives, benzotriazoles, organophosphorus compounds, phenylenediamine compounds, 2-amino-1-phenylethanol, N-phenylethanolamine, N-ethyldiethanolamine, N-ethylethanolamine and derivatives, benzothiazole, and a benzothiazoleamine salt having a cyclohexyl ring and a morpholine ring, 3-glycidoxypropyltrimethoxysilane, 3-glycidoxypropyltriethoxysilane, 3-mercaptopropyltrimethoxysilane, 3-mercaptopropyltriethoxysilane, 3-methacryloyloxypropyltrimethoxysilane, vinyl trimethoxysilane, combinations thereof, or the like.

Surface leveling agents are added to some embodiments of the resist to assist a top surface of the photoresist to be level, so that impinging light will not be adversely modified by an unlevel surface. In some embodiments, surface leveling agents include fluoroaliphatic esters, hydroxyl terminated fluorinated polyethers, fluorinated ethylene glycol polymers, silicones, acrylic polymer leveling agents, combinations thereof, or the like.

In some embodiments, the polymer, monomer, or oligomer, and the PACs, along with any desired additives or other agents, are added to the solvent for application. Once added, the mixture is then mixed in order to achieve a homogenous composition throughout the photoresist to ensure that there are no defects caused by uneven mixing or nonhomogenous composition of the photoresist. Once mixed together, the photoresist may either be stored prior to its usage or used immediately.

Once ready, the photoresist is applied onto the layer to be patterned (S110), as shown in FIG. 2, such as the substrate 10 to form a photoresist layer 15. In some embodiments, the photoresist is applied using a process such as a spin-on coating process, a dip coating method, an air-knife coating method, a curtain coating method, a wire-bar coating method, a gravure coating method, a lamination method, an extrusion coating method, combinations of these, or the like. In some embodiments, the photoresist layer 15 thickness ranges from about 10 nm to about 300 nm.

After the photoresist layer 15 has been applied to the substrate 10, a pre-exposure bake (S120) of the photoresist layer is performed in some embodiments to cure and dry the photoresist prior to radiation exposure (see FIG. 1). The curing and drying of the photoresist layer 15 removes solvent while leaving behind the polymer, photoactive compound, and the other chosen additives. In some embodiments, the pre-exposure baking (S120) is performed at a temperature suitable to evaporate the solvent, such as between about 40° C. and 120° C., although the precise temperature depends upon the materials chosen for the photoresist. The pre-exposure baking is performed for a time sufficient to cure and dry the photoresist layer, such as between about 10 seconds to about 10 minutes.

FIGS. 3A and 3B illustrate selective exposures of the photoresist layer to form an exposed region 50 and an unexposed region 52. In some embodiments, the exposure to radiation is carried out by placing the photoresist coated substrate in a photolithography tool. The photolithography tool includes a photomask 30/65, optics, an exposure radiation source to provide the radiation 45/97 for exposure, and a movable stage for supporting and moving the substrate under the exposure radiation.

In some embodiments, the radiation source (not shown) supplies radiation 45/97, such as ultraviolet light, to the photoresist layer 15, and the radiation is absorbed by the polymer, the photoactive compound, or metal particles in order to induce a reaction in the photoresist layer to chemically alter those regions of the photoresist layer to which the radiation 45/97 impinges. In some embodiments, the radiation is electromagnetic radiation, such as g-line (wavelength of about 436 nm), i-line (wavelength of about 365 nm), ultraviolet radiation, far ultraviolet radiation, extreme ultraviolet, electron beams, or the like. In some embodiments, the radiation source is selected from the group consisting of a mercury vapor lamp, xenon lamp, carbon arc lamp, a KrF excimer laser light (wavelength of 248 nm), an ArF excimer laser light (wavelength of 193 nm), an F₂ excimer laser light (wavelength of 157 nm), or a CO₂ laser-excited Sn plasma (extreme ultraviolet, wavelength of 13.5 nm).

In some embodiments, optics (not shown) are used in the photolithography tool to expand, reflect, or otherwise control the radiation before or after the radiation 45/97 is patterned by the photomask 30/65. In some embodiments, the optics include one or more lenses, mirrors, filters, and combinations thereof to control the radiation 45/97 along its path.

In some embodiments, the exposure of the photoresist layer 15 uses an immersion lithography technique. In such a technique, an immersion medium (not shown) is placed between the final optics and the photoresist layer, and the exposure radiation 45 passes through the immersion medium.

After the photoresist layer 15 has been exposed to the exposure radiation 45 (S130), a post exposure baking (S140) is performed in some embodiments to further the reaction initiated during the selective exposure to actinic radiation. In some embodiments including a photoactive compound, the post exposure baking assists in the photocleaving of the polymer and the generating, dispersing, and reacting of the acid/base/free radical generated from the impingement of the radiation 45 upon the PACs during the exposure. Such thermal assistance helps to create or enhance chemical reactions, which generate chemical differences between the exposed region 50 and the unexposed region 52 within the photoresist layer 15. These chemical differences also cause differences in the solubility between the exposed region 50 and the unexposed region 52. In some embodiments, the post exposure baking (S140) occurs at temperatures ranging from about 70° C. to about 160° C. for a period of between about 20 seconds and about 120 seconds.

In some embodiments, the photoresist developer 57 includes a solvent, and an acid or a base. In some embodiments, the concentration of the solvent is from about 60 wt. % to about 99 wt. % based on the total weight of the photoresist developer. The acid or base concentration is from about 0.001 wt. % to about 20 wt. % based on the total weight of the photoresist developer. In certain embodiments, the acid or base concentration in the developer is from about 0.01 wt. % to about 15 wt. % based on the total weight of the photoresist developer.

In some embodiments, the developer includes a solvent selected from the group consisting of propylene glycol methyl ether acetate (PGMEA), propylene glycol monomethyl ether (PGME), 1-ethoxy-2-propanol (PGEE), 7-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), 2-heptanone (MAK), and isobutyl propionate. In other embodiments, the developer is an aqueous solvent, including a tetramethylammonium hydroxide (TMAH) solution.

In some embodiments, the developer 57 is applied to the photoresist layer 15 using a spin-on process. In the spin-on process, the developer 57 is applied to the photoresist layer 15 from above the photoresist layer 15 while the photoresist coated substrate is rotated, as shown in FIG. 4. In some embodiments, the developer 57 is supplied at a rate of between about 5 ml/min and about 800 ml/min, while the photoresist coated substrate 10 is rotated at a speed of between about 100 rpm and about 2000 rpm. In some embodiments, the developer is at a temperature of between about 10° C. and about 80° C. The development operation (S150) continues for between about 30 seconds to about 10 minutes in some embodiments.

While the spin-on operation is one suitable method for developing the photoresist layer 15 after exposure, it is intended to be illustrative and is not intended to limit the embodiment. Rather, any suitable development operations, including dip processes, puddle processes, and spray-on methods, may alternatively be used. All such development operations are included within the scope of the embodiments.

During the development process (S150), the developer 57 dissolves the radiation-unexposed regions 52 of negative-tone resists or negative-tone developed resists to form a pattern 55a, exposing the surface of the substrate 10, as shown in FIG. 5A, leaving behind well-defined exposed photoresist regions 50, having improved definition than provided by conventional negative photoresist photolithography. In other embodiments, the developer 57 dissolves the radiation-exposed regions 50 of positive-tone resists to form a pattern 55b, exposing the surface of the substrate 10, as shown in FIG. 5B, leaving behind well-defined unexposed photoresist regions 52, having improved definition than provided by conventional positive photoresist photolithography.

After the developing operation S150, remaining developer is removed from the patterned photoresist covered substrate. The remaining developer is removed using a spin-dry process in some embodiments, although any suitable removal technique may be used. After the photoresist layer 15 is developed, and the remaining developer is removed, additional processing is performed while the patterned photoresist layer (exposed region 50, unexposed region 52) is in place. For example, an etching operation, using dry or wet etching, is performed in some embodiments, to transfer the pattern 55a, 55b of the photoresist layer to the underlying substrate 10, forming recesses 55a′, 55b′ as shown in FIGS. 6A and 6B. The substrate 10 has a different etch resistance than the photoresist layer 15. In some embodiments, the etchant is more selective to the substrate 10 than the photoresist layer 15.

In some embodiments, the substrate 10 and the photoresist layer 15 contain at least one etching resistance molecule. In some embodiments, the etching resistant molecule includes a molecule having a low Onishi number structure, a double bond, a triple bond, silicon, silicon nitride, titanium, titanium nitride, aluminum, aluminum oxide, silicon oxynitride, combinations thereof, or the like.

In some embodiments, a target layer 60 to be patterned is disposed over the substrate prior to forming the photoresist layer, as shown in FIG. 7. In some embodiments, the target layer 60 is a metallization layer or a dielectric layer, such as a passivation layer, disposed over a metallization layer. In embodiments where the target layer 60 is a metallization layer, the target layer 60 is formed of a conductive material using metallization processes, and metal deposition techniques, including chemical vapor deposition, atomic layer deposition, physical vapor deposition (sputtering), or electroplating. Likewise, if the target layer 60 is a dielectric layer, the target layer 60 is formed by dielectric layer formation techniques, including thermal oxidation, chemical vapor deposition, atomic layer deposition, and physical vapor deposition.

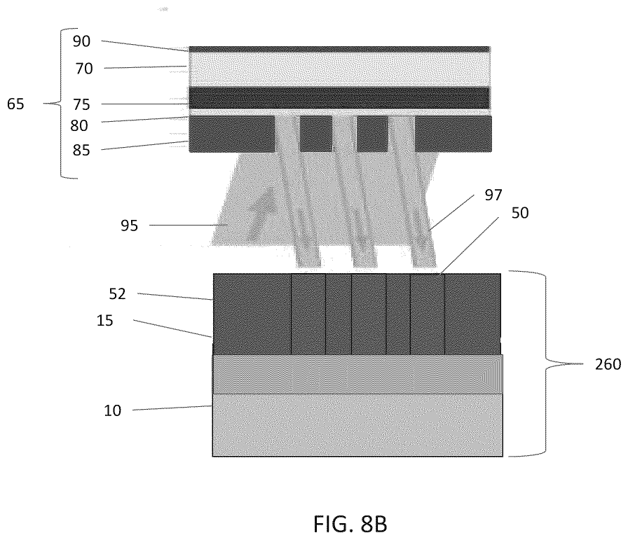

The photoresist layer 15 is subsequently selectively exposed to actinic radiation 45/97 to form exposed regions 50 and unexposed regions 52 in the photoresist layer, as shown in FIGS. 8A and 8B, and described herein in relation to FIGS. 3A and 3B. The exposed photoresist coated substrate 260 is subsequently post-exposure baked (S140).

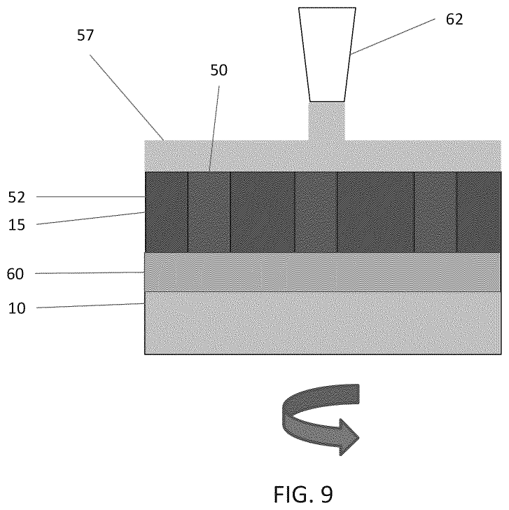

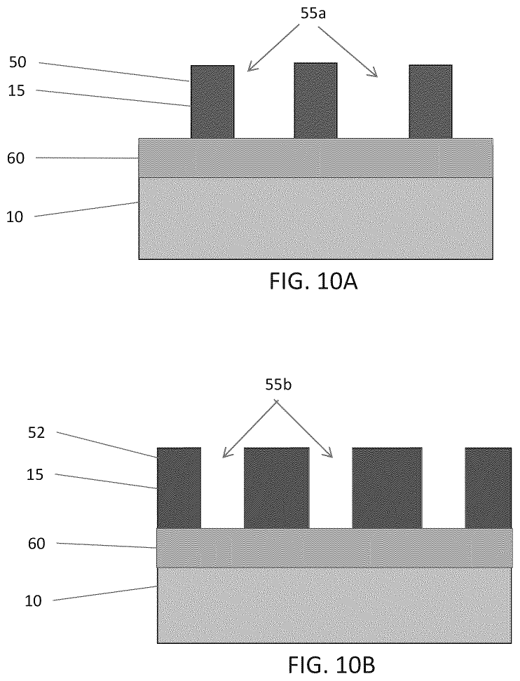

As shown in FIG. 9, the photoresist layer 15 is developed by dispensing developer 57 from a dispenser 62 to form a pattern of photoresist openings 55a, 55b, as shown in FIGS. 10A and 10B. The development operation is similar to that explained with reference to FIGS. 4-5B, herein. In some embodiments, where the photoresist is a negative-tone resist or negative-tone developed resist, the unexposed portion of the photoresist layer 52 is removed by the developer 57 forming a pattern of openings 55a in the photoresist layer 15 to expose the target layer 60, as shown in FIG. 10A. In other embodiments, where the photoresist is a positive-tone resist, the exposed portion of the photoresist layer 50 is removed by the developer 57 forming a pattern of openings 55b in the photoresist layer 15 to expose the target layer 60, as shown in FIG. 10B.

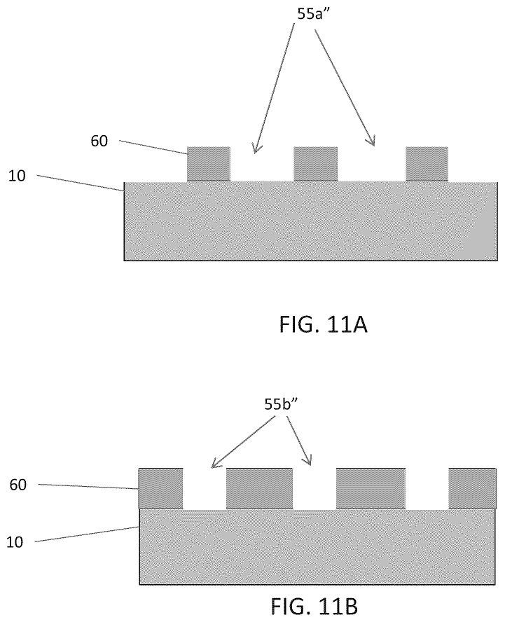

Then as shown in FIGS. 11A and 11B, the pattern 55a, 55b in the photoresist layer 15 is transferred to the target layer 60 using an etching operation and the photoresist layer is removed, as explained with reference to FIGS. 6A and 6B to form the pattern 55a″, 55b″ in the target layer 60.

Other embodiments include other operations before, during, or after the operations described above. In some embodiments, the disclosed methods include forming semiconductor devices, including fin field effect transistor (FinFET) structures. In some embodiments, a plurality of active fins are formed on the semiconductor substrate. Such embodiments, further include etching the substrate through the openings of a patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In some embodiments, one or more gate electrodes are formed on the substrate. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, FinFETs, other three-dimensional (3D) FETs, other memory cells, and combinations thereof are formed, according to embodiments of the disclosure.

The novel photoresist compositions and semiconductor device manufacturing methods according to the present disclosure provide higher semiconductor device feature yield. Embodiments of the present disclosure include methods and materials that reduce scum defects, thereby improving pattern resolution, decreasing line width roughness, decreasing line edge roughness, and improving semiconductor device yield. Embodiments of the disclosure further enables the use of lower exposure doses to effectively expose and pattern the photoresist.

An embodiment of the disclosure is a method of manufacturing a semiconductor device, including forming a photoresist layer including a photoresist composition over a substrate. The photoresist layer is selectively exposed to actinic radiation, the selectively exposed photoresist layer is developed to form a pattern in the photoresist layer. The photoresist composition includes a polymer including monomer units with photocleaving promoters, wherein the photocleaving promoters are one or more selected from the group consisting of a living free radical polymerization chain transfer agent, an electron withdrawing group, a bulky two dimensional (2-D) or three dimensional (3-D) organic group, a N-(acyloxy)phthalimide, and an electron stimulated radical generator. In an embodiment, the photoresist composition includes a photoacid generator. In an embodiment, the photoresist composition includes an electron stimulated radical generator additive. In an embodiment, the electron stimulated radical generator additive is a 1,4-benzoquinone. In an embodiment, the photocleaving promoters include an electron withdrawing group selected from the group consisting of a halogen, —CHO, —C(═O)R, —C(═O)OR, —C(═O)OH, —C(═O)Cl, —CF₃, —CN, —SO₃H, —(NH₃)⁺, —(NR₃)⁺, —N⁺(═O)O, where R is a C1-C40 alkyl group, a C1-C40 alkoxy group, a C1-C40 alkyl ester group, a C1-C40 hydroxyalkyl group, a C1-C40 alkyl amine group, a C1-C40 alkyl group substituted with an acid labile group (ALG) at a —C(═O)— or —C(═O)O— site pendant to the alkyl group, a C1-C40 alkene group, a C6-C40 aryl group, a C1-C40 alkyl amide group, a C7-C40 aralkyl group, and combinations thereof. In an embodiment, the photocleaving promoters include a bulky 2-D or 3-D organic group selected from the group consisting of a C4-C16 tert-alkyl group, a C6-C12 cycloalkyl group, a phenyl group, a napthalenyl group, a phenanthrenyl group, an anthracenyl group, a triphenyl methyl group, a norbornyl group, a cubanyl group, an adamantyl group, a basketanyl group, and combinations thereof. In an embodiment, the bulky 2-D or 3-D group is substituted with one or more of a halogen, an —OH, a C1-C40 alkyl group, a C2-C40 alkyl ether group, a C2-C40 alkyl ester group, a C1-C40 hydroxyalkyl group, a C1-C40 alkyl amine group, a C2-C40 alkene group, a phenyl group, an anthracenyl group, a C1-C40 alkyl carboxylic acid group, or a C1-C40 alkyl amide group. In an embodiment, the photocleaving promoters include an N-(acetyloxy)phthalimide. In an embodiment, the photocleaving promoters include an electron stimulated radical generator, and the electron stimulated radical generator is a 1,4-benzoquinone group. In an embodiment, the photocleaving promoters include a living free radical polymerization chain transfer agent as a polymer backbone terminal unit of the polymer. In an embodiment, the living free radical polymerization chain transfer agent is selected from the group consisting of F, Cl, Br, I, a —ON(C(CH₃)₃)₂ group, a (2,2,6,6-tetramethylpiperidin-1-yl)oxyl group, a —SC(═S)Z group, and a —SC(═S)SZ, where Z is a C1-C20 alkyl group, a C6-C20 aryl group, and a C7-C20 aralkyl group. In an embodiment, the developing forms a negative tone developed pattern.

Another embodiment of the disclosure is a method for manufacturing a semiconductor device, including forming a resist layer comprising a resist composition over a target layer, and patterning the resist layer. The resist composition includes a polymer including one or more monomer units selected having substituents selected from the group consisting of electron withdrawing groups, two dimensional (2-D) or three dimensional (3-D) organic groups, N-(acyloxy)phthalimides, and electron stimulated radical generators; or the polymer includes terminal units including a living free radical polymerization chain transfer agent. In an embodiment, the resist composition includes the polymer having terminal units including a living free radical polymerization chain transfer agent, wherein the living free radical chain transfer unit is selected from the group consisting of of F, Cl, Br, I, a —ON(C(CH₃)₃)₂ group, a (2,2,6,6-tetramethylpiperidin-1-yl)oxyl group, a —SC(═S)Z group, and a —SC(═S)SZ group where Z is a C1-C20 alkyl group, a C6-C20 aryl group, or a C7-C20 aralkyl group. In an embodiment, the resist composition includes the polymer including one or more monomer units including an electron withdrawing group selected from the group consisting of a halogen, —C(═O)H, —C(═O)R, —C(═O)OR, —C(═O)OH, —C(═O)Cl, —CF₃, —CN, —SO₃H, —(NH₃)⁺, —(NR₃)⁺, —N⁺(═O)O, where R is a C1-C40 alkyl group, a C1-C40 alkoxy group, a C1-C40 alkyl ester group, a C1-C40 hydroxyalkyl group, a C1-C40 alkyl amine group, a C1-C40 alkyl group substituted with an acid labile group (ALG) at a —C(═O)— or —C(═O)O— site pendant to the alkyl group, a C1-C40 alkene group, a C6-C40 aryl group, a C1-C40 alkyl amide group, a C7-C40 aralkyl group, or combinations thereof. In an embodiment, the resist composition includes a 2-D or 3-D organic group selected from the group consisting of a C4-C16 tert-alkyl group, a C6-C12 cycloalkyl group, a phenyl group, a napthalenyl group, a phenanthrenyl group, an anthracenyl group, a triphenyl methyl group, a norbornyl group, a cubanyl group, an adamantyl group, a basketanyl group, and combinations thereon, wherein the 2-D or 3-D organic group is unsubstituted or substituted with one or more of a halogen, an —OH, a C1-C40 alkyl group, a C2-C40 alkyl ether group, a C1-C40 alkyl ester group, a C1-C40 hydroxyalkyl group, a C1-C40 alkyl amine group, a C1-C40 alkene group, a phenyl group, an anthracenyl group, a C1-C40 alkyl carboxylic acid group, and a C1-C40 alkyl amide group. In an embodiment, the resist composition includes a substituted or unsubstituted N-(acyloxy)phthalimide.

Another embodiment of the disclosure is a method for manufacturing a semiconductor device, including forming a photoresist layer including a photoresist composition over a substrate. The photoresist layer is selectively exposed to actinic radiation to form a latent pattern, and the latent pattern is developed to form a pattern in the photoresist layer. The photoresist composition includes a polymer made of monomer units u, v, x, y, and z represented by a structure:

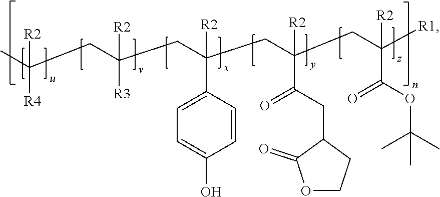

where: R1 is selected from the group consisting of F, Cl, Br, I, a —ON(C(CH₃)₃)₂ group, a (2,2,6,6-tetramethylpiperidin-1-yl)oxyl group, a —SC(═S)Z group, and a —SC(═S)SZ group, where Z is a C1-C20 alkyl group, a C6-C20 aryl group, or a C7-C20 aralkyl group; R2 is selected from the group consisting of H, a halogen, —C(═O)H, —C(═O)R, —C(═O)OR, —C(═O)OH, —C(═O)Cl, —CF₃, —CN, —SO₃H, —(NH₃)⁺, —(NR₃)⁺, —N⁺(═O)O, where R is a C1-C40 alkyl group, a C1-C40 alkoxy group, a C1-C40 alkyl ester group, a C1-C40 hydroxyalkyl group, a C1-C40 alkyl amine group, a C1-C40 alkyl group substituted with an acid labile group (ALG) at a —C(═O)— or —C(═O)O— site pendant to the alkyl group, a C2-C40 alkene group, a C6-C40 aryl group, a C1-C40 alkyl amide group, a C7-C40 aralkyl group, a C4-C16 tert-alkyl group, a C6-C12 cycloalkyl group, a phenyl group, a napthalenyl group, a phenanthrenyl group, an anthracenyl group, a triphenyl methyl group, a norbornyl group, a cubanyl group, an adamantyl group, a basketanyl group, or combinations thereof; R3 is a substituted or unsubstituted N-(acyloxy)phthalimide; R4 is an electron stimulated radical generator; and a molar concentration of each monomer unit u, v, x, y, and z ranges from 0% to 100%, wherein at least one of the monomer units u, v, x, y, and z is included in the polymer. In an embodiment, the polymer is made of 1% to 100% of monomer units u or v. In an embodiment, the polymer includes a substituted or unsubstituted N-(acyloxy)phthalimide. In an embodiment, the developing forms a negative tone developed pattern

Another embodiment of the disclosure is a composition, including a polymer made of monomer units u, v, x, y, and z represented by a structure:

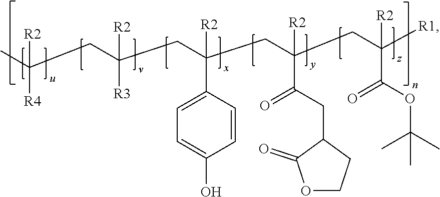

where: R1 is selected from the group consisting of F, Cl, Br, I, a —ON(C(CH₃)₃)₂ group, a (2,2,6,6-tetramethylpiperidin-1-yl)oxyl group, a —SC(═S)Z group, and a —SC(═S)SZ group, where Z is a C1-C20 alkyl group, a C6-C20 aryl group, or a C7-C20 aralkyl group; R2 is selected from the group consisting of H, a halogen, —C(═O), —C(═O)R, —C(═O)OR, —C(═O)OH, —C(═O)Cl, —CF₃, —CN, —SO₃H, —(NH₃)⁺, —(NR₃)⁺, —N⁺(═O)O, where R is a C1-C40 alkyl group, a C1-C40 alkoxy group, a C2-C40 alkyl ester group, a C1-C40 hydroxyalkyl group, a C1-C40 alkyl amine group, a C1-C40 alkyl group substituted with an acid labile group (ALG) at a —C(═O)— or —C(═O)O— site pendant to the alkyl group, a C2-C40 alkene group, a C6-C40 aryl group, a C1-C40 alkyl amide group, a C7-C40 aralkyl group, a C4-C16 tert-alkyl group, a C6-C12 cycloalkyl group, a phenyl group, a napthalenyl group, a phenanthrenyl group, an anthracenyl group, a triphenyl methyl group, a norbornyl group, a cubanyl group, an adamantyl group, a basketanyl group, and combinations thereof; R3 is a substituted or unsubstituted N-(acyloxy)phthalimide; R4 is an electron stimulated radical generator; and a molar concentration of each monomer unit u, v, x, y, and z ranges from 0% to 100%, wherein at least one of the monomer units u, v, x, y, and z is included in the polymer. The composition includes a solvent. In an embodiment, the composition includes a photoactive compound. In an embodiment, the photoactive compound is a photoacid generator. In an embodiment, the polymer is made of 1% to 100% of monomer units u or v. In an embodiment, the polymer includes a substituted or unsubstituted N-(acyloxy)phthalimide. In an embodiment, the polymer includes monomer unit u, and R4 is is a 1,4-benzoquinone group. In an embodiment, the composition includes an electron stimulated radical generator additive. In an embodiment, the electron stimulated radical generator additive is a substituted or unsubstituted 1,4-benzoquinone. In an embodiment, a concentration of the electron stimulated radical generator ranges from 1 wt. % to 60 wt. % based on the total weight of the electron stimulated radical generator, the polymer, and the photoacid generator.

Another embodiment of the disclosure is a composition, including a polymer including monomer units with photocleaving promoters, wherein the photocleaving promoters are one or more selected from the group consisting of a living free radical polymerization chain transfer agent, an electron withdrawing group, a bulky two dimensional (2-D) or three dimensional (3-D) organic group, a N-(acyloxy)phthalimide, and an electron stimulated radical generator. The composition includes a photoactive compound and a solvent. In an embodiment, the photoactive compound includes a photoacid generator. In an embodiment, the composition includes an electron stimulated radical generator additive. In an embodiment, the electron stimulated radical generator additive is 1,4-benzoquinone or a benzoquinone substituted with a C1-C40 alkyl group, a C2-C40 alkoxide group, a C2-C40 alkyl ester group, a C1-C40 hydroxyalkyl group, a C1-C40 alkyl amine group, a C1-C40 alkyl substituted with an acid labile group via a —CO— or a —COO— linkage, a C2-C40 alkene group, a C6-C40 aryl group, a C7-C40 aralkyl group, a phenyl group, a naphthalenyl group, an anthracenyl group, a phenanthrenyl group, a C1-C40 alkyl carboxylic acid group, a C1-C40 alkyl amide group. In an embodiment, the photocleaving promoters include an electron withdrawing group selected from the group consisting of a halogen, —C(═O), —C(═O)R, —C(═O)OR, —C(═O)OH, —C(═O)Cl, —CF₃, —CN, —SO₃H, —(NH₃)⁺, —(NR₃)⁺, —N⁺(═O)O, where R is a C1-C40 alkyl group, a C2-C40 alkoxy group, a C2-C40 alkyl ester group, a C1-C40 hydroxyalkyl group, a C1-C40 alkyl amine group, a C1-C40 alkyl group substituted with an acid labile group (ALG) at a —C(═O)— or —C(═O)O— site pendant to the alkyl group, a C2-C40 alkene group, a C6-C40 aryl group, a C1-C40 alkyl amide group, a C7-C40 aralkyl group, and combinations thereof. In an embodiment, the photocleaving promoters include a bulky 2-D or 3-D organic group selected from the group consisting of a C4-C16 tert-alkyl group, a C6-C12 cycloalkyl group, a phenyl group, a napthalenyl group, a phenanthrenyl group, an anthracenyl group, a triphenyl methyl group, a norbornyl group, a cubanyl group, an adamantyl group, a basketanyl group, and combinations thereof. In an embodiment, the bulky 2-D or 3-D group is substituted with one or more of a halogen, an —OH, a C1-C40 alkyl group, a C2-C40 alkyl ether group, a C2-C40 alkyl ester group, a C1-C40 hydroxyalkyl group, a C1-C40 alkyl amine group, a C2-C40 alkene group, a phenyl group, an anthracenyl group, a C1-C40 alkyl carboxylic acid group, and a C1-C40 alkyl amide group. In an embodiment, the photocleaving promoters include N-(acetyloxy)phthalimide or N-(acetyloxy)phthalimide substituted with a C1-C40 alkyl group, a C1-C40 alkoxide group, a C1-C40 alkyl ester group, a C1-C40 hydroxyalkyl group, a C1-C40 alkyl amine group, a C1-C40 alkyl substituted with an acid labile group via a —C(═O)— or a —C(═O)O— linkage, a C2-C40 alkene group, a C6-C40 aryl group, a C7-C40 aralkyl group, a phenyl group, a naphthalenyl group, an anthracenyl group, a phenanthrenyl group, a C1-C40 alkyl carboxylic acid group, a C1-C40 alkyl amide group. In an embodiment, the photocleaving promoters include a 1,4-benzoquinone group as the electron stimulated radical generator. In an embodiment, the photocleaving promoters include a living free radical polymerization chain transfer agent selected from the group consisting of F, Cl, Br, I, a —ON(C(CH₃)₃)₂ group, a (2,2,6,6-tetramethylpiperidin-1-yl)oxyl group, a —SC(═S)Z group, and a —SC(═S)SZ group, where Z is a C1-C20 alkyl group, a C6-C20 aryl group, or a C7-C20 aralkyl group, as a polymer backbone terminal unit of the polymer. In an embodiment, the composition includes a quencher.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a photoresist layer comprising a photoresist composition over a substrate;
selectively exposing the photoresist layer to actinic radiation; and
developing the selectively exposed photoresist layer to form a pattern in the photoresist layer,
wherein the photoresist composition comprises a polymer including monomer units with photocleaving promoters, and
the photocleaving promoters are one or more selected from the group consisting of a living free radical polymerization chain transfer agent, an electron withdrawing group, a bulky two dimensional (2-D) or three dimensional (3-D) organic group, an N-(acyloxy)phthalimide, and an electron stimulated radical generator.

2. The method according to claim 1, wherein the photoresist composition further comprises a photoacid generator.

3. The method according to claim 1, wherein the photoresist composition further comprises an electron stimulated radical generator additive.

4. The method according to claim 3, wherein the electron stimulated radical generator additive is a 1,4-benzoquinone.

5. The method according to claim 1, wherein the photocleaving promoters include an electron withdrawing group selected from the group consisting of a halogen, —C(═O)H, —C(═O)R, —C(═O)OR, —C(═O)OH, —C(O)Cl, —CF₃, —CN, —SO₃H, —(NH₃)⁺, —(NR₃)⁺, —N⁺(═O)O, where R is a C1-C40 alkyl group, a C1-C40 alkoxy group, a C2-C40 alkyl ester group, a C1-C40 hydroxyalkyl group, a C1-C40 alkyl amine group, a C1-C40 alkyl group substituted with an acid labile group (ALG) at a —C(═O)— or —C(═O)O— site pendant to the alkyl group, a C2-C40 alkene group, a C6-C40 aryl group, a C1-C40 alkyl amide group, a C7-C40 aralkyl group, and combinations thereof.

6. The method according to claim 1, wherein the photocleaving promoters include a bulky 2-D or 3-D organic group selected from the group consisting of a C4-C16 tert-alkyl group, a C6-C12 cycloalkyl group, a phenyl group, a napthalenyl group, a phenanthrenyl group, an anthracenyl group, a triphenyl methyl group, a norbornyl group, a cubanyl group, an adamantyl group, a basketanyl group, and combinations thereof.

7. The method according to claim 6, wherein the bulky 2-D or 3-D group is substituted with one or more of a halogen, an —OH, a C1-C40 alkyl group, a C2-C40 alkyl ether group, a C2-C40 alkyl ester group, a C1-C40 hydroxyalkyl group, a C1-C40 alkyl amine group, a C2-C40 alkene group, a phenyl group, an anthracenyl group, a C1-C40 alkyl carboxylic acid group, or a C1-C40 alkyl amide group.

8. The method according to claim 1, wherein the photocleaving promoters include an N-(acetyloxy)phthalimide.

9. The method according to claim 1, wherein the photocleaving promoters include an electron stimulated radical generator, and the electron stimulated radical generator is a 1,4-benzoquinone group.

10. The method according to claim 1, wherein the photocleaving promoters include a living free radical polymerization chain transfer agent as a polymer backbone terminal unit of the polymer.

11. The method according to claim 10, wherein the living free radical polymerization chain transfer agent is selected from the group consisting of F, Cl, Br, I, a —ON(C(CH₃)₃)₂ group, a (2,2,6,6-tetramethylpiperidin-1-yl)oxyl group, a —SC(═S)Z group, and a —SC(═S)SZ group, where Z is a C1-C20 alkyl group, a C6-C20 aryl group, or a C7-C20 aralkyl group.

12. The method according to claim 1, wherein the developing forms a negative tone developed pattern.

13. A method for manufacturing a semiconductor device, comprising:
forming a resist layer comprising a resist composition over a target layer; and
patterning the resist layer;
wherein the resist composition comprises a polymer including one or more monomer units having substituents selected from the group consisting of an electron withdrawing group, a two dimensional (2-D) or three dimensional (3-D) organic group, an N-(acyloxy)phthalimide, and an electron stimulated radical generator; or a polymer comprising terminal units including a living free radical polymerization chain transfer agent.

14. The method according to claim 13, wherein the resist composition includes the polymer comprising terminal units including a living free radical polymerization chain transfer agent, wherein the living free radical chain transfer unit is selected from the group consisting of of F, Cl, Br, I, a —ON(C(CH₃)₃)₂ group, a (2,2,6,6-tetramethylpiperidin-1-yl)oxyl group, a —SC(═S)Z group, and a —SC(═S)SZ group, where Z is a C1-C20 alkyl group, a C6-C20 aryl group, or a C7-C20 aralkyl group.

15. The method according to claim 13, wherein the resist composition includes the polymer including one or more monomer units having an electron withdrawing group selected from the group consisting of a halogen, —C(═O)H, —C(═O)R, —C(═O)OR, —C(═O)OH, —C(O)Cl, —CF₃, —CN, —SO₃H, —(NH₃)⁺, —(NR₃)⁺, —N⁺(═O)O, where R is a C1-C40 alkyl group, a C2-C40 alkoxy group, a C2-C40 alkyl ester group, a C1-C40 hydroxyalkyl group, a C1-C40 alkyl amine group, a C1-C40 alkyl group substituted with an acid labile group (ALG) at a —C(═O)— or —C(═O)O— site pendant to the alkyl group, a C2-C40 alkene group, a C6-C40 aryl group, a C1-C40 alkyl amide group, a C7-C40 aralkyl group, and combinations thereof.

16. The method according to claim 13, wherein, wherein the resist composition includes the polymer including one or more monomer units including a 2-D or 3-D organic group selected from the group consisting of a C4-C16 tert-alkyl group, a C6-C12 cycloalkyl group, a phenyl group, a napthalenyl group, a phenanthrenyl group, an anthracenyl group, a triphenyl methyl group, a norbornyl group, a cubanyl group, an adamantyl group, a basketanyl group, and combinations thereon, and
the 2-D or 3-D organic group is unsubstituted or substituted with one or more of a halogen, an —OH, a C1-C40 alkyl group, a C2-C40 alkyl ether group, a C1-C40 alkyl ester group, a C1-C40 hydroxyalkyl group, a C1-C40 alkyl amine group, a C2-C40 alkene group, a phenyl group, an anthracenyl group, a C1-C40 alkyl carboxylic acid group, and a C1-C40 alkyl amide group.

17. The method according to claim 13, wherein the resist composition includes a substituted or unsubstituted N-(acyloxy)phthalimide.

18. A composition, comprising:
a polymer made of monomer units u, v, x, y, and z represented by a structure: 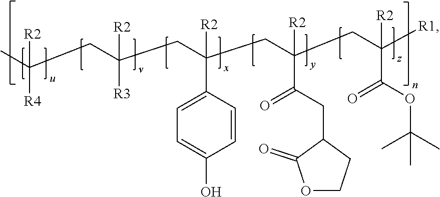
where:
R1 is selected from the group consisting of F, Cl, Br, I, a —ON(C(CH₃)₃)₂ group, a (2,2,6,6-tetramethylpiperidin-1-yl)oxyl group, a —SC(═S)Z group, and a —SC(═S)SZ group, where Z is a C1-C20 alkyl group, a C6-C20 aryl group, or a C7-C20 aralkyl group;
R2 is selected from the group consisting of H, a halogen, —C(═O)H, —C(═O)R, —C(═O)OR, —C(═O)OH, —C(═O)Cl, —CF₃, —CN, —SO₃H, —(NH₃)⁺, —(NR₃)⁺, —N⁺(═O)O, where R is a C1-C40 alkyl group, a C2-C40 alkoxy group, a C2-C40 alkyl ester group, a C1-C40 hydroxyalkyl group, a C1-C40 alkyl amine group, a C1-C40 alkyl group substituted with an acid labile group (ALG) at a —C(═O)— or —C(═O)O— site pendant to the alkyl group, a C2-C40 alkene group, a C6-C40 aryl group, a C1-C40 alkyl amide group, a C7-C40 aralkyl group, a C4-C16 tert-alkyl group, a C6-C12 cycloalkyl group, a phenyl group, a napthalenyl group, a phenanthrenyl group, an anthracenyl group, a triphenyl methyl group, a norbornyl group, a cubanyl group, an adamantyl group, a basketanyl group, and combinations thereof;
R3 is a substituted or unsubstituted N-(acyloxy)phthalimide;
R4 is an electron stimulated radical generator; and
a molar concentration of each monomer unit u, v, x, y, and z ranges from 0% to 100%,
wherein at least one of the monomer units u, v, x, y, and z is included in the polymer; and
a solvent.

19. The composition of claim 18, further comprising a photoactive compound.

20. The composition of claim 18, wherein the polymer is made of 1% to 100% of monomer units u or v.
